(19) United States
(12) Patent Application Publication
(10) Pub. No.: US 2024/0020448 A1
(43) Pub. Date: Jan. 18, 2024

(54) CIRCUIT AND METHOD FOR SIMULATING A REAL-TIME RECONFIGURABLE GENERAL-PURPOSE MEMRISTOR

(71) Applicant: UNIVERSITY OF ELECTRONIC SCIENCE AND TECHNOLOGY OF CHINA, Chengdu (CN)

(72) Inventors: Bo XU, Chengdu (CN); Hang GENG, Chengdu (CN); Libing BAI, Chengdu (CN); Yuhua CHENG, Chengdu (CN); Kai CHEN, Chengdu (CN); Songting ZOU, Chengdu (CN)

(73) Assignee: UNIVERSITY OF ELECTRONIC SCIENCE AND TECHNOLOGY OF CHINA, Chengdu (CN)

(21) Appl. No.: 17/969,516

(22) Filed: Oct. 19, 2022

(30) Foreign Application Priority Data
Jul. 14, 2022 (CN) 202210826639.X
Jul. 14, 2022 (CN) 202210826653.X

(51) Int. Cl. G06F 30/347; H03K 19/177

(52) U.S. Cl. CPC G06F 30/347; H03K 19/177

(57) ABSTRACT

A circuit and method for simulating real-time reconfigurable general-purpose memristor, nonlinear m-order polynomial fitting of mathematical model of a memristor is performed by using McLaughlin formula. m is related to the amplitude and frequency of an input signal and the fitting accuracy, thus the mathematical model of a memristor can be easily and quickly adapted by updating the polynomial order, the polynomial coefficients and the FPGA system clock cycle. Based on the FPGA, a system state variable generation module, a FIFO, a output module are used to obtain an output signal y[n]. the detailed steps of signal processing and displaying are given to obtain a display of a pinched hysteresis loop and a waveform display of time-domain. Simulation of high frequency memristor by setting polynomial coefficients can be obtained. Meanwhile, this is built based on FPGA, adopt digital circuit to simulates a reconfigurable general-purpose memristor, and experimental accuracy is enhanced.

### FIELD OF THE INVENTION

This application claims priorities under the Paris Convention to Chinese Patent Applications No. 202210826639.X and 202210826653.X, filed on Jul. 14, 2022, the entirety of which is hereby incorporated by reference for all purposes as if fully set forth herein.

The present invention relates to the field of memristor simulator, more particularly to a circuit and method for simulating real-time reconfigurable general-purpose memristor.

### BACKGROUND OF THE INVENTION

In 1971, Professor Leon O. Chua firstly proposed a theoretical model of memristor according to circuit complete theorem, and considered that the memristor was the fourth basic two-terminal circuit element besides resistor, capacitor and inductor, which described a nonlinear relationship between charge and magnetic flux. Meanwhile, Professor Leon O. Chua also gave out three basic characteristics for memristor: \textcircled{1} when a memristor is excited by a bipolar periodic electric signal, its curve in V-I plane is a pinched hysteresis loop, \textcircled{2} when the scanning frequency of the electric signal increases, the area of the lobe of the pinched hysteresis loop will decrease, \textcircled{3} when the scanning frequency of the electric signal approaches infinity, the pinched hysteresis loop will shrink to a single-valued function.

In a nano film based on titanium dioxide, a physical memristor was firstly realized in by Stan William's team at Hewlett-Packard Laboratories in 2008, it was not until then that the research of memristor's characteristics and application was paid close attention by a great many researchers. From then on, the memristor proposed by Professor Leon O. Chua has not been a theoretical model, but a real component. And now, the model of memristor has been wildly applied to various technical fields, such as neural network, machine learning, chaos theory, secure communication, image encryption, non-volatile memory and filter circuit. Unfortunately, on the one hand, the different material used to make a memristor corresponds to the different physical mechanism, which makes the characteristics of a memristor different from that of other and limits the large scale application of memristor. For example, researchers have found the characteristic of pinched hysteresis loop in various materials such as binary oxide, complex perovskite oxide, solid electrolyte materials, amorphous carbon materials, organic polymeric materials, and proposed various physical mechanisms such as the conductive channel's formation and break caused by vacancy migration of oxygen, contact barrier modulation, the metal conductive channel's formation and break caused by active electrode's metallization, the capture and release of injected carrier and metal-insulator transition to explain their memristor characteristics. On the other hand, at present there isn't any commercial memristor in the market. For example, memristor Knowm is seen as a commercial component, but for the reason that its structure is quite complex and its cost is very high, it is difficult to be applied in large scale. Facing various complex physical mechanisms and high manufacture cost, it is very urgent and important to design a circuit for simulating real-time reconfigurable general-purpose memristor, which can be applicable to multiple physical models, to analyze the relevant characteristics of memristor by experiment.

The relevant scholars have done a lot of researches on the bandwidth (frequency) enhancement of the circuit for simulating memristor. Analog method, digital-analog hybrid method and application specific integrated circuit method have been used to build memristor simulator circuits to verify the characteristics and measure the bandwidths of various memristors.

In analog method, a lot of passive components (such as resistors, capacitors and inductors) and active components (such as operational amplifier, operational transconductance amplifier (OTA), current-feedback operational amplifier (CFOA), Differential Difference Current Conveyor (DDCC) and analog multiplier) are used to build a memristor simulator circuit, which is a breadboard or a circuit board. The experimental bandwidth of the memristor simulator circuit has been enhanced from 500 Hz of the early period to 1.3 MHz of the present. Meanwhile, positive and negative power supply is used in the memristor simulator circuit. In analog method, for different model and bandwidth of memristor, we need to redesign a memristor simulator circuit and spend a lot of time on circuit debugging. Furthermore, to the input signal of MHz, the experimental result can't be verified by using a breadboard, because the parasitic parameters of signal transmission line, impedance match and signal crosstalk can't be solved. Only circuit board can output signals which can be displayed as a pinched hysteresis loop by using the oscilloscope's function of Lissajous figure. Notably, a great error exists in the analog method, and the sources of the error are mainly as follows: the errors of 5%, 20% and 20% respectively of most commercial resistors, capacitors and inductors, the errors occurred from the input voltage offset (Vos) and the input bias current, and the errors occurred from the different effects of the non-linearity of active component's analog bandwidth on different signals' amplitude-frequency curves. As so far, the memristor simulator circuit of bandwidth of 10 MHz and above has not been realized in analog method.

For the reason that very professional knowledge of electronic circuit is needed in circuit design and debugging, it is very difficult for most of scholars who are engaged in basic study. So the relevant scholars further proposed digital-analog hybrid method, which usually adopts ADC, programmable general-purpose processor and DAC to realize a memristor simulator circuit, where ADC and DAC are respectively used to the analogy-digital quantization of an input signal and the digital-analogy conversion of the output signal, programmable general-purpose processor is used to realize the real-time calculation of the value of memristance or memductance. Comparing to analog method, digital-analog hybrid method is more simple and efficient to realize a memristor simulator circuit, but it also has the following limits: can't simulate a memristor of high frequency due to the computation speed of programmable general-purpose processor, operating frequency of ADC, operating frequency of DAC and analog bandwidth, can't simulate a memristor of high-precision hardware due to the resolutions of ADC, DAC and digital oscilloscope and the amplitude range of output signal.

To the known memristor model, the relevant scholars also proposed application specific integrated circuit method. In the paper of “Memristor emulator circuits using single CBTA” (U. E. Ayten, S. Minaei and M. Sa\check{g}baş, AEU—International Journal of Electronics and Communications, volume 82, pages 109-118, December, 2017), a memristor simulator circuit with ±0.9V power supply has been realized by using 23 CMOS transistors. In the paper of “A new grounded memristor emulator based on MOSFET-C,” (Abdullah Yesil, AEU—International Journal of Electronics and Communications, volume 91, pages 143-149, July, 2018), a memristor emulator circuit consisting of only seven MOS transistors and one grounded capacitor was presented. The memristor circuit was laid by using Cadence Environment with TSMC 0.18 μm process parameters and its layout dimensions are only 12 μm×38 μm excluding the area of the capacitor. All post-layout simulations agree well with theoretical analyses. Obviously, application specific integrated circuit method can dramatically reduces the size of memristor simulator circuit and enhance the precision of implementation. But the complicated design process and high implementation cost is a major hindrance to wide application. Meanwhile, application specific integrated circuit method is only applicable to a known memristor model, and not applicable to the study of multiple memristor models.

Generally speaking, firstly, most of memristor simulator circuits in prior art can only simulate the dynamic behavior of a memristor at relative lower frequency, in other words, the memristor simulator circuits can only exhibit a pinched hysteresis loop at the frequency less than the critical frequency, and a liner resistor at the frequency beyond the critical frequency, which limits their the application in high speed, high bandwidth fields, such as generation of high-frequency random signal, transmission of high-speed data and storage of high-speed data. Secondly, all of memristor simulator circuits in prior art are fixed model oriented designs, so the researchers will spend a lot of time and effort on the work from the theoretic model to the actual output of memristor simulator circuit, and in most cases, the engineers having professional circuit background are needed to be involved in hardware debugging Meanwhile, all of the three methods in prior art can't realize the real-time reconfigurable memristor according to memristor model. So the hardware realization of memristor simulator circuit is a time consuming, inefficient and complicated process. Finally, the inherent error of component, transmission loss in circuit and the error of measurement instrument in memristor simulator circuit are very important to the high-precision hardware realization of a memristor's theoretical model, but as so far, the experimental accuracy of memristor simulator circuit has not been highly concerned by relevant scholars.

### SUMMARY OF THE INVENTION

The present invention aims to overcome the deficiencies of the prior art, and provides a circuit and method for simulating real-time reconfigurable general-purpose memristor, which can be applicable to different models of memristor, simulate high-frequency memristor and enhance the experimental accuracy of memristor simulator circuit.

To achieve these objectives, in accordance with the present invention, a circuit for simulating real-time reconfigurable general-purpose memristor, which is built based on a FPGA is provided, comprising:
a system state variable generation module, which comprises a multiplier, an accumulator and an adder, where in the multiplier is used to multiply an input signal x[n] and a FPGA system clock cycle Ts together to obtain a result Ts·x[n], and result Ts·x[n] is outputted to the accumulator for accumulation to obtain an accumulated value, which is denoted by:

$$Ts \cdot {{\sum }_{j = 1}}^{n} x [ j ]$$

the accumulated value is outputted to the adder to add a system state variable's initial value [0], then a system state variable h[n] is obtained:

$$h [ n ] = T s {\sum }_{j = 1}^{n} x [ j ] + h [ 0 ]$$

where the input signal x[n] is a voltage signal or current signal, the system state variable h[n] is a charge or magnetic flux variable;
a calculation module, which comprises m reconfigurable calculating units operating in m grades cascaded pipeline mode, and is used to implement m polynomial multiply-accumulate operations, wherein each reconfigurable calculating unit comprises two multipliers, one adder and one D flip-flop;
to i+1^{th} reconfigurable calculating unit, i=0, 1, 2, . . . , m−1, its inputs are polynomial coefficient k[i+1], the adder's input s[i] and the first multiplier's inputs H[i] and d[i], its outputs are the adder's output s[i+1], the second multiplier's output H[i+1] and the delayed signal d[i+1], the mathematical relation of the inputs and the outputs is:

$$\{ \begin{matrix}H [ i + 1 ] = H [ i ] \cdot d [ i ] \\ s [ i + 1 ] = s [ i ] + k [ i + 1 ] \cdot H [ i + 1 ] \\ d [ i + 1 ] = d [ i ]\end{matrix}$$

where the first multiplier is used to multiply inputs H[i] and d[i] together to obtain the output H[i+1], the second multiplier is used to multiply the first multiplier's output H[i+1] and polynomial coefficient k[i+1] together to obtain an output k[i+1]·H[i+1], the adder is used to add the input s[i] and the output k[i+1]·H[i+1] together to obtain the output s[i+1], the D flip-flop is used to delay the input d[i] to obtain the delay signal d[i+1];
to the 1^{st} reconfigurable calculating unit, its input d[0] is the system state variable h[n] outputted by system state variable generation module, its input H[0] is 1, its input s[0] is the polynomial coefficient k(0);
wherein the number m of the polynomials is determined as follows:
determining the maximum amplitude aₘₐₓ and the minimum frequency ωₘᵢₙ respectively according to the amplitude and the frequency of the zero-DC component AC signal in the input signal x[n], then determining the range of the system state variable h[n] as follows:

$$[ - \frac{{a}_{max}}{{ω}_{min}} , \frac{{a}_{max}}{{ω}_{min}} ]$$

in the range of the system state variable h[n], using McLaughlin formula to perform a m-order polynomial fitting of memristance or memductance f(h[n]) about the system state variable h[n] to obtain a fitting function g(h[n]), where the maximum fitting error ε_{M} is:

$${ε}_{M} = \vert \frac{f ( \frac{{a}_{max}}{{ω}_{min}} ) - g ( \frac{{a}_{max}}{{ω}_{min}} )}{f ( \frac{{a}_{max}}{{ω}_{min}} )} \vert$$

the value of the polynomial order m should satisfy ε_{M}≤ε₀, where ε₀ is the acceptable maximum fitting error;
wherein the polynomial coefficient k[i] of the i^{th} order, i=0, 1, 2, . . . , m is obtained by expanding the mathematical model of memristor to be simulated, i.e. the memristance or memductance f(h[n]) at time n into a polynomial according to McLaughlin formula:

$$f ( h [ n ] ) = {\sum }_{i = 0}^{m} k [ i ] \cdot {( h [ n ] )}^{i}$$

the output s[m] of the m^{th} reconfigurable calculating unit is taken as the memristance or memductance f(h[n]);
a FIFO, which is used to delay the input signal x[n] m+39 clock periods to obtain a delayed input signal;
a output module, which comprises a multiplier, where the multiplier is used to multiply the delayed input signal and the memristance or memductance f(h[n]) outputted by the m^{th} reconfigurable calculating unit to obtain an output signal y[n], the output signal y[n] is a current signal or a voltage signal.

In addition, in accordance with the present invention, a method for simulating real-time reconfigurable general-purpose memristor is provided, comprising:
(1). establishing a mathematical model f(h[n]) for a memristor, and judging whether it is a polynomial about a system state variable h[n], if not, going to step (2), if it is, then determining an m-order of the mathematical model f(h[n]) about the system state variable h[n] and going to step (5);
(2). determining the maximum amplitude aₘₐₓ and the minimum frequency ωₘᵢₙ respectively according to the amplitude and the frequency of the zero-DC component AC signal in an input signal x[n], then determining the range of the system state variable h[n] as follows:

$$[ - \frac{{a}_{max}}{{ω}_{min}} , \frac{{a}_{max}}{{ω}_{min}} ]$$

(3). in the range of the system state variable h[n], using McLaughlin formula to perform a m-order polynomial fitting of memristance or memductance f(h[n]) about the system state variable h[n] to obtain a fitting function g(h[n]), where the maximum fitting error ε_{M} is:

$${ε}_{M} = \vert \frac{f ( \frac{{a}_{max}}{{ω}_{min}} ) - g ( \frac{{a}_{max}}{{ω}_{min}} )}{f ( \frac{{a}_{max}}{{ω}_{min}} )} \vert$$

the value of the polynomial order m should satisfy ε_{M}≤ε₀, where ε₀ is the acceptable maximum fitting error;
(4). determining m+1 polynomial coefficients kᵢ, i=0, 1, 2, . . . , m of the mathematical model f(h[n]) according to McLaughlin formula;
(5). simulating the memristor in real time based on a FPGA, i.e. performing the following calculations in the FPGA:
5.1). firstly, to input signal x[n], converting it into a single precision floating-point data f_x[n] by using the fixed point number to floating point number IP core in the FPGA, where the range of the single precision floating-point data f_x[n] is [−1, 1], then, calculating an system state variable h[n], i.e. the charge or magnetic flux at time n:

$$h [ n ] = Ts {\sum }_{{J}^{1}}^{n} f\_x [ j ] + h [ 0 ]$$

where Ts is the system clock cycle of the FPGA, f_x[j] is the j^{th} sampling point of the single precision floating-point data f_x[n], h[0] is the initial value of the system state variable h[n];
5.2). calculating the mathematical model f(h[n]), i.e. the memristance or memductance f(h[n]) of the memristor:

$$f ( h [ n ] ) = {\sum }_{i = 0}^{m} {k}_{i} \cdot {( h [ n ] )}^{i}$$

5.3). meanwhile, sending the single precision floating-point data f_x[n] to a FIFO, i.e. the first FIFO for delay to obtain a delayed data f_dly_x[n], which makes the data of the read port of the first FIFO, i.e. delayed data f_dly_x[n] aligned with the memristance or memductance f(h[n]) along the time, then calculating the output signal y[n]:

y[n]=f(h[n])·f_dly_x[n]
where the input signal x[n] is a voltage signal or current signal, the output signal y[n] is a current signal or voltage signal;
(6). storing the delayed data f_dly_x[n] and the output signal y[n] into another FIFO, i.e. the second FIFO, when the second FIFO is written full, reading out the delayed data f_dly_x[n] and the output signal y[n] from the second FIFO and send them to a signal processing and displaying module;
(7). in the signal processing and displaying module, multiplying the vertical sensitivity of input signal displaying and the half of the number of the vertical divisions in waveform display area to obtain a display range R₁, multiplying the vertical sensitivity of memristor output displaying and the half of the number of the vertical divisions in waveform display area to obtain a display range R₂;
then processing the delayed data f_dly_x[n] as follows:

$${d}_{x} ( n ) = f\_dly \_x [ n ] \cdot {R}_{1}$$

$${d}_{x \_ HL} ( n ) = \frac{{d}_{x} ( n )}{max ( \vert {d}_{X} ( n ) \vert )} \cdot {R}_{1}$$

where max(|dₓ(n)|) represents choosing the data which absolute value is maximum from the sequence of data dₓ(n), data d_{x_HL}(n)∈[−1, 1];
processing the output data y[n] as follows:

$${d}_{y} ( n ) = y [ n ] \cdot \frac{{R}_{2}}{{R}_{1}}$$

$${d}_{y \_ HL} ( n ) = \frac{{d}_{y} ( n )}{max ( \vert {d}_{y} ( n ) \vert )} \cdot {R}_{2}$$

where max(|d_{y}(n)|) represents choosing the data which absolute value is maximum from the sequence of data d_{y}(n), data d_{y_HL}(n)∈[−1, 1];
(8) taking the center of the waveform display area of the X-Y view of a digital oscilloscope as a coordinate origin (0, 0), respectively taking the data d_{x_HL}(n) as a x-coordinate and the data d_{y_HL}(n) as a y-coordinate, then sending the pixel (d_{x_HL}(n), d_{y_HL}(n)) as the pixel to be highlighted into the digital oscilloscope's LCD to perform a display of Lissajous figure, i.e. display a pinched hysteresis loop; meanwhile, sending the data dₓ(n) and the data d_{y}(n) into the digital oscilloscope for caching and then performing a waveform display of time-domain;
(9). resetting the second FIFO, then judging according to the following rules: if both of the polynomial coefficient k(i) and the range of the system state variable h[n] have not been changed, then going to step (6), if the polynomial coefficient k(i) has been changed and the range of the system state variable h[n] has not been changed, then going to step (5), otherwise, going to step (1).

The objectives of the present invention are realized as follows:

In the present invention of a circuit and method for simulating real-time reconfigurable general-purpose memristor, nonlinear m-order polynomial fitting of mathematical model of a memristor is performed by using McLaughlin formula, wherein m is related to the amplitude and frequency of an input signal and the fitting accuracy, thus the mathematical model of a memristor can be easily and quickly adapted by updating the polynomial order, the polynomial coefficients and the FPGA system clock cycle. On this basis, based on the FPGA, a circuit for simulating real-time reconfigurable general-purpose memristor is provided, in which, a system state variable generation module is built to generate a system state variable, i.e. charge or magnetic flux variable, a calculation module is built for the m-stage reconfigurable calculation of polynomial coefficients and the system state variable to obtain a memristance or memductance, a FIFO is used to make the input signal, a voltage signal or a current signal aligned with the memristance or memductance f(h[n]) along the time, a output module is used to multiply the delayed input signal and the memristance or memductance f(h[n]) to obtain an output signal y[n], which is a current signal or a voltage signal. Meanwhile, method for simulating real-time reconfigurable general-purpose memristor is provided, in which, the detailed steps of signal processing and displaying are given to obtain a display of Lissajous figure, i.e. a pinched hysteresis loop and a waveform display of time-domain. In addition, the present invention can simulate high frequency memristor by setting polynomial coefficients, i.e. using lower frequency signal to realize the equivalent verification of the memristor's characteristics of high frequency signal, which is a prominent advantage that makes the research of memristor's characteristics less concerned about the analog bandwidth of memristor simulator circuit and is very convenient to most of researchers who has not very professional knowledge of electronic circuit design and debugging. Meanwhile, the present invention is built based on FPGA, adopt digital circuit to simulates a reconfigurable general-purpose memristor, the experimental accuracy is enhanced.

### BRIEF DESCRIPTION OF THE DRAWING

The above and other objectives, features and advantages of the present invention will be more apparent from the following detailed description taken in conjunction with the accompanying drawings, in which:

FIG. 1(a)-FIG. 1(f) are curve diagrams of q-f(q) drawn according to different polynomial coefficients of 2-order mathematic model of memristor, where FIG. 1(a) corresponds to polynomial coefficients k₂≠0, k₁≠0 and k₀≠0, and f(q) is unipolar, FIG. 1(b) corresponds to polynomial coefficients k₂≠0, k₁≠0 and k₀≠0, and f(q) is bipolar, FIG. 1(c) corresponds to polynomial coefficients k₂≠0, k₁=0, and f(q) is unipolar/bipolar, FIG. 1(d) corresponds to polynomial coefficients k₂=0, k₁≠0 and k₀≠0 and f(q) is bipolar, FIG. 1(e) corresponds to polynomial coefficients k₂=0, k₁≠0 and k₀=0, and f(q) is bipolar, FIG. 1(f) corresponds to polynomial coefficients k₂=0, k₁≠0 and k₀=0, and f(q) is bipolar;

FIG. 2 is a diagram of approximate curve of ω-L,

FIG. 3(a)-FIG. 3(b) are diagrams of time-domain waveform curves in numerical simulation 1, where FIG. 3(a) corresponds to input voltage signal, FIG. 3(b) corresponds to output current signal, FIG. 3(c) is a diagram of characteristic curve of the general mathematic model of memristor of the present invention on a U-I plane.

FIG. 4(a)-FIG. 4(b) are comparison diagrams of characteristic curves of different frequencies respectively under the cosine input signal's amplitudes of 1V and 2V;

FIG. 5(a)-FIG. 5(d) are comparison diagrams of pinched hysteresis loops of different polynomial coefficients in numerical simulation 2, where FIG. 5(a) corresponds to coefficient matrix K=K₂, FIG. 5(b)-FIG. 5(d) correspond to coefficients k₁, k₂ and k₂ expanded 10 times respectively;

FIG. 6(a)-FIG. 6(f) are diagrams of pinched hysteresis loops of different amplitudes and frequencies of input signal in numerical simulation 3 respectively under sampling frequencies 100 MSa/s and 200 GSa, where FIG. 6(a) corresponds to sampling frequency of 100 MSa/s and 5 different frequencies input signals of 0.1V, FIG. 6(b) corresponds to sampling frequency of 100 MSa/s and 5 different frequencies input signals of 1V, FIG. 6(c) corresponds to sampling frequency of 100 MSa/s and 5 different frequencies input signals of 2V, FIG. 6(d) corresponds to sampling frequency of 200 MSa/s and 5 different frequencies input signals of 0.1V, FIG. 6(e) corresponds to sampling frequency of 200 MSa/s and 5 different frequencies input signals of 1V, FIG. 6(f) corresponds to sampling frequency of 200 MSa/s and 5 different frequencies input signals of 2V;

FIG. 7(a)-FIG. 7(c) are diagrams of the pinched hysteresis loops of different frequencies input signal based on oversampling, where FIG. 7(a) corresponds to 500 Khz input signal, FIG. 7(b) corresponds to 1 Mhz input signal, FIG. 7(c) corresponds to 2 Mhz input signal;

FIG. 8(a)-FIG. 8(d) are diagrams of the pinched hysteresis loops of different coefficient matrix in numerical simulation 4, which show the active characteristics of the general mathematic model of memristor, where FIG. 8(a) corresponds to coefficient matrix K_{4.0}, FIG. 8(b) corresponds to coefficient matrix K_{4.1}, FIG. 8(c) corresponds to coefficient matrix K_{4.2}, FIG. 8(d) corresponds to coefficient matrix K_{4.3};

FIG. 9(a)-FIG. 9(d) are diagrams of the pinched hysteresis loops of different coefficient matrix in numerical simulation 5, which show impacts on area of pinched hysteresis loop while changing polynomial coefficients, where FIG. 9(a) corresponds to coefficient matrix K_{5.0}, FIG. 9(b) corresponds to coefficient matrix K_{5.1}, FIG. 9(c) corresponds to coefficient matrix K_{5.2}, FIG. 9(d) corresponds to coefficient matrix K_{5.3};

FIG. 10(a)-FIG. 10(c) are diagrams of the time-domain waveforms and pinched hysteresis loops respectively under 200 Gsa/s and 100 MSa/s, where FIG. 10(a) corresponds to 200 Gsa/s, FIG. 10(b) corresponds to 100 Msa/s, FIG. 10(c) corresponds to the combined diagrams of both sampling frequencies;

FIG. 11 is a diagram of a circuit for simulating real-time reconfigurable general-purpose memristor in accordance with one embodiment of the present invention;

FIG. 12 is a diagram of one embodiment of the reconfigurable calculating unit shown in FIG. 11;

FIG. 13 is a flow diagram of a method for simulating real-time reconfigurable general-purpose memristor in accordance with one embodiment of the present invention;

FIG. 14 is a diagram of the hardware implementation of simulating real-time reconfigurable general-purpose memristor in accordance with one embodiment of the present invention;

FIG. 15 is a timing diagram of the hardware simulation in accordance with one embodiment of the present invention;

FIG. 16(a) and FIG. 16(b) are comparison diagrams of pinched hysteresis loops respectively obtained by Matlab software and a FPGA, where FIG. 16(a) corresponds to the overall pinched hysteresis loops, FIG. 16(b) corresponds to the partial pinched hysteresis loops.

### DETAILED DESCRIPTION OF THE PREFERRED EMBODIMENT

Hereinafter, preferred embodiments of the present invention will be described with reference to the accompanying drawings. It should be noted that the similar modules are designated by similar reference numerals although they are illustrated in different drawings. Also, in the following description, a detailed description of known functions and configurations incorporated herein will be omitted when it may obscure the subject matter of the present invention.

1. The General Mathematic Model of Memristor of the Present Invention

Since the constitutive relation (theoretical model) of memristor is derived according to circuit complete theorem by Professor Leon O. Chua in 1971, many researchers have studied the theoretical model of memristor. In 2008, Stan William's team at Hewlett-Packard Laboratories observed the phenomenon of memristance in lab, the finding made the memristor advanced from the theoretical model to physical implementation.

Memristor in nature is a nonlinear dynamical system, and general mathematic model of memristor defined as follows:

$$\{ \begin{matrix}y ( t ) = f ( x ( t ) , h ) x ( t ) \\ \dot{h} = g ( x ( t ) , h )\end{matrix} \qquad ( 1 )$$

where f(x(t),h) is a continuous and bounded function about an independent variable, x(t), y(t) respectively are the input voltage (current) signal and the input current (voltage) signal of memristor, f(x(t),h) is memductance or memristance, h is the time derivative of state vector. If x(t)=U(t), then formula (1) is called a voltage controlled memristor, If x(t)=/(t), then formula (1) is called a voltage controlled memristor, U(t) is an input voltage signal, I(t) is an input current signal.

When f(x(t),h) can be approximated uniformly by m-order polynomial function sequence fₘ(x(t),h), the general mathematic model of memristor expressed by formula (1) can be further expressed as follows:

$$\{ \begin{matrix}y ( t ) = a \cdot {f}_{m} ( x ( t ) , h ) \cdot x ( t ) \\ {f}_{m} ( x ( t ) , h ) = {\sum }_{i = 0}^{m} {k}_{i} \cdot {( x ( t ) )}^{i} \\ h ( x ( t ) ) = {\int }_{{t}_{0}}^{t} x ( τ ) d τ + h ( {t}_{0} )\end{matrix} \qquad ( 2 )$$

where K=(k₀, k₁, . . . , kₘ) is a coefficient matrix, and K≠0, h(x(t)) is a charge or magnetic flux variable, h(x(t₀) is the initial value of charge or magnetic flux variable. α is the amplitude factor of the output signal y(t). When the input signal x(t) is a voltage signal or current signal, the memristor expressed by formula (2) is a voltage controlled memristor or a current controlled memristor. In term of the mathematical model, the only differences of the two kinds of memristor are different physical units of input signal x(t), output signal y(t) and system state variable h(x(t), i.e. charge or magnetic flux variable. Thus, to simplify the expression, α is set to 1.

The general mathematical model of memristor expressed by formula (2) is a continuous expression, however, the continuous model can be processed in general-purpose digital processing circuit. Formula (2) is quantified by time interval Ts, a discrete model of memristor is obtained as follows:

$$\{ \begin{matrix}y [ n ] = {f}_{m} ( x [ n ] , h ) \cdot x [ n ] \\ {f}_{m} ( x [ n ] , h ) = {\sum }_{i = 0}^{m} {k}_{i} \cdot {( h ( x [ n ] ) )}^{i} \\ h ( x [ n ] ) = Ts {\sum }_{i = 1}^{n} x [ i ] + h [ 0 ]\end{matrix} \qquad ( 3 )$$

In present invention, time interval Ts is the FPGA system clock cycle. To simplify the expression, h(x[n]) is simplified as h[n], fₘ(x[n],h) is simplified as f(h[n]), then the general mathematical model of memristor in present invention is obtained:

$$\{ \begin{matrix}y [ n ] = f ( h [ n ] ) \cdot x [ n ] \\ {f ( h [ n ] ) = {\sum }_{i = 0}^{m} {k}_{i} \cdot ( h [ n ] ) )}^{i} \\ h [ n ] = Ts {\sum }_{i = 1}^{n} x [ i ] + h [ 0 ]\end{matrix} \qquad ( 4 )$$

2. The Generality of the General Mathematic Model of Memristor of the Present Invention

In the general mathematic model of memristor proposed by the present invention, the amplitude a and frequency co of the input signal x(t) are known, so the range of system state variable h(t) is fixed and bounded. With Weierstrass first theorem, general mathematic model f(h(t)) can be fitted by using a m-order polynomial. The Taylor formula and McLaughlin formula have given a concrete method for realizing the m-order polynomial. The greater the order m is chosen, the higher the approximation accuracy of f(h(t)), accordingly, the higher the calculation complexity of f(h(t)). Thus the accuracy, speed and logic resource must be balanced when the general mathematic model f(h(t)) is implemented in general-purposed processor such as FPGA. To discrete general mathematic model f(h[n]), we can use formula (4) to approximate. Table 1 shows multiple mathematic models of memristor obtained by configuring coefficient matrix K and polynomial order m.

TABLE 1

| Mathematic | polynomial coefficient k | | | | | | | | | | |
|---|---|---|---|---|---|---|---|---|---|---|---|
| model | k₀ | k₁ | k₂ | k₃ | k₄ | k₅ | k₆ | k₇ | k₈ | k₉ | k₁₀ |
| a + b tanh x | a | b | 0 | $- \frac{b}{3}$ | 0 | $\frac{2 b}{15}$ | 0 | $- \frac{17 b}{315}$ | 0 | $\frac{62 b}{2835}$ | 0 |
| a cos x | a | 0 | $- \frac{a}{2 !}$ | 0 | $\frac{a}{4 !}$ | 0 | $- \frac{a}{6 !}$ | 0 | $\frac{a}{8 !}$ | 0 | $- \frac{a}{10 !}$ |
| a sin(cx) + bx² | 0 | ac | b | $- \frac{{ac}^{3}}{3 !}$ | 0 | $\frac{{ac}^{5}}{5 !}$ | 0 | $- \frac{{ac}^{7}}{7 !}$ | 0 | $\frac{{ac}^{9}}{9 !}$ | 0 |
| a ± bx | a | ±b | 0 | 0 | 0 | 0 | 0 | 0 | 0 | 0 | 0 |
| a + 3bx² | a | 0 | 3b | 0 | 0 | 0 | 0 | 0 | 0 | 0 | 0 |
| a + bx² + cx⁴ | a | 0 | b | 0 | c | 0 | 0 | 0 | 0 | 0 | 0 |

As shown in Tablet, the discrete general mathematic model of memristor of the present invention has compatibility to the models of memristor in prior art.

3. The Generality of the General Mathematic Model of Memristor of the Present Invention to Active or Passive Memristor

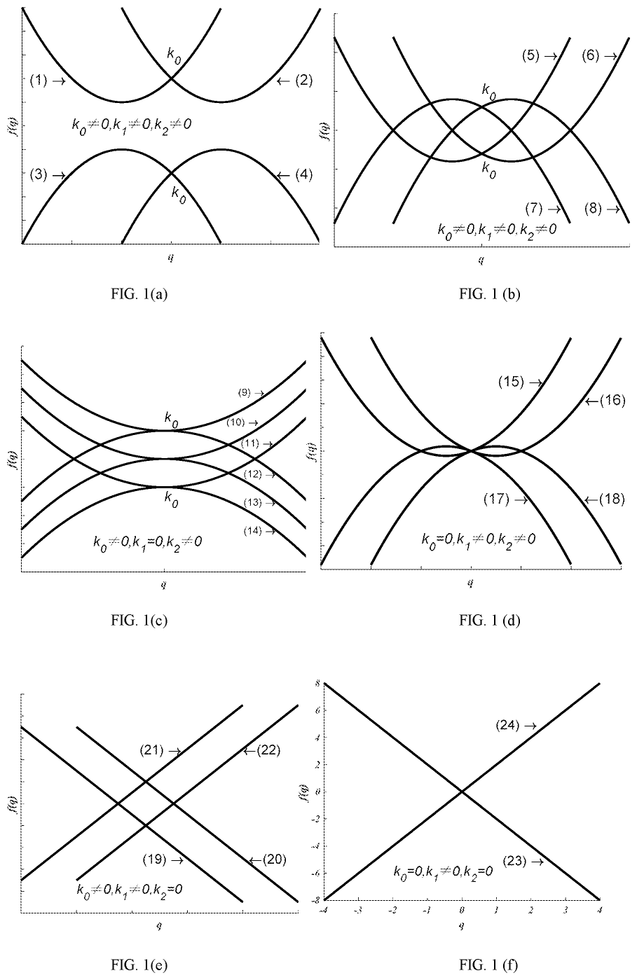

The polarity of the general mathematic model f(h(t)) of memristor is related to coefficient matrix K and system state variable h(t). To illustrate the effects of the two parameters, we choose magnetic flux variable q as system state variable h(t) and a mathematical model of charge (voltage) controlled memristor with 2-order. Then the general mathematic model f(q) of memristor can be expressed as:

$$f ( q ) = {k}_{2} {q}^{2} + {k}_{1} q + {k}_{0} = \{ \begin{matrix}{k}_{1} q + {k}_{0} , ( {k}_{2} = 0 ) \\ {{k}_{2} ( q + \frac{{k}_{1}}{2 {k}_{2}} )}^{2} + \frac{4 {k}_{0} {k}_{2} - {k}_{1}^{2}}{4 {k}_{2}} , ( {k}_{2} \neq 0 )\end{matrix} \qquad ( 5 )$$

where polynomial coefficient k₁ and k₂ can't be 0 simultaneously, otherwise the memristor will become a linear time-invariance resistor. The curves of q-f(q) have 24 kinds of figures as shown in FIG. 1 according to the values of k₀, k₁ and k₂, and from the FIG. 1, we can see that the curve of q-f(q) can be above, under or across the horizontal axis.

If the pinched hysteresis loop of a memristor is distributed only on the first quadrant and/or the third quadrant under the excitation of any one zero-DC component AC periodical signal, the memristor is passive, otherwise, is active. The pinched hysteresis of active memristor may not cross the zero point, because when the pinched hysteresis loop is distributed on the second quadrant or the forth quadrant, x(t)y(t)≤0, the behavior of active memristor is similar to a energy source. In formula (1), the independent invariables f(x(t),h) and x(t) to the right of the equal sign determine the polarity of the dependent invariable y(t) to the left of the equal sign. When a zero-DC bipolar signal x(t) is inputted to a memristor, the pinched hysteresis loop on U-I plane has three cases as shown in Table 2.

TABLE 2

| | | Dependent | | |
|---|---|---|---|---|
| Independent | | invari- | Outputs | |
| invariable | | able | Pinched hysteresis | Type of |
| f (x(t), h) | x(t) | y(t) | loop | memristor |
| ≥0 | ≥0 | ≥0 | On the first quadrant | Passive |
| ≥0 | ≤0 | ≤0 | On the third quadrant | memristor |
| ≤0 | ≥0 | ≤0 | On the forth quadrant | Active |
| ≤0 | ≤0 | ≥0 | On the second quadrant | memristor |
| Bipolar | | | On all quadrant | Partly active |
| | | | | memristor |

As shown in Table 2, case1: if independent invariables f(x(t),h) is positive, the pinched hysteresis loop on U-I plane is distributed on the first quadrant and the third quadrant, the memristor is a passive memristor, case 2: if independent invariables f(x(t),h) is negative, the pinched hysteresis loop on U-I plane is distributed on the second quadrant and the forth quadrant, the memristor is an active memristor, case 3: if independent invariables f(x(t),h) is bipolar, the pinched hysteresis loop on the U-I plane is distributed on all quadrants, the memristor is partly active memristor. The models corresponding to curves (1), (2), (11) and curves (3), (4), (14) are respectively passive memristors and active memristors, the models corresponding to the rest curves are partly active memristors.

4. The Non-Linear Characteristic Analysis of the General Mathematic Model of Memristor of the Present Invention

To verify the input signal's bandwidth of the general mathematical model of memristor in formula (4), here we use cosine signal as input to perform theoretical bandwidth analysis. The input signal is x(t)=a cos(ωt), where a is the amplitude of the input signal, ω is the angular frequency of the input signal. The starting time of excitation is t₀, letting x(t₀)=0, h(t₀)=0, the mathematical model h(t) is as follows:

$$h ( t ) = {\int }_{0}^{t} a cos ( ω ξ ) d ξ = \frac{a sin ( ω t )}{ω} \qquad ( 6 )$$

where

$$h ( t ) ∈ [ \frac{- a}{ω} , \frac{a}{ω} ]$$

for

$$cos ( ω t ) = \frac{x ( t )}{a} ,$$

we can easily calculate out:

$$sin ( ω t ) = \{ \begin{matrix}\frac{\sqrt{{a}^{2} - {x}^{2} ( t )}}{a} , t ∈ [ 0 , \frac{π}{ω} ) \\ \frac{- \sqrt{{a}^{2} - {x}^{2} ( t )}}{a} , t ∈ [ \frac{π}{c o} , \frac{2 π}{ω} ]\end{matrix} \qquad ( 7 )$$

Then the mathematical model f(h(t)) can be expressed as follows:

$$\begin{matrix}f ( h ( t ) ) = {\sum }_{0}^{m} {{k}_{i} ( h ( t ) )}^{i} \\ = {k}_{0} + {k}_{1} \frac{a}{ω} sin ( ω t ) + {k}_{2} \frac{{a}^{2}}{{ω}^{2}} {sin}^{2} ( ω t ) + … + {k}_{m} \frac{{a}^{m}}{{ω}^{m}} {sin}^{m} ( ω t ) \\ = {k}_{0} + {\sum }_{i = 1}^{m} {{k}_{i} ( - 1 )}^{i} \frac{{[ {a}^{2} - {x}^{2} ( t ) ]}^{\frac{i}{2}}}{{ω}^{i}}\end{matrix} \qquad ( 8 )$$

Finally, we can obtain the input-output signal expression as follows:

$$\begin{matrix}y ( t ) = f [ h ( t ) ] \cdot x ( t ) \\ = {k}_{0} x ( t ) + {\sum }_{i = 1}^{m} {{k}_{i} ( - 1 )}^{i} \frac{{[ {a}^{2} - {x}^{2} ( t ) ]}^{\frac{i}{2}}}{{ω}^{i}} x ( t ) \\ = {y}_{1} ( t ) + {y}_{2} ( t ) \\ {y}_{1} ( t ) = {k}_{0} x ( t ) \\ {y}_{2} ( t ) = {\sum }_{i = 1}^{m} {{k}_{i} ( - 1 )}^{i} \frac{{[ {a}^{2} - {x}^{2} ( t ) ]}^{\frac{i}{2}}}{{ω}^{i}} x ( t )\end{matrix} \qquad ( 9 )$$

From the expression shown in formula (9), the output y(t) is composed of linear term y₁(t) and nonlinear term y₂(t).

When k₀≠0, in formula (9), as the angular frequency co decreases, the nonlinear term y₂(t) will increase, under this circumstance, the output y(t) is mainly determined by the nonlinear term y₂(t). On the contrary, as the angular frequency co decreases, the nonlinear term y₂(t) will decrease, under this circumstance, the output y(t) is mainly determined by the linear term y₁(t), and the linear term y₁(t) can be explained as a standard linear component, for example, when the input is a voltage signal, the output y(t) is a standard admittance component.

Letting

$$l = \frac{{y}_{2} ( t )}{{y}_{1} ( t )} ,$$

there is:

$$l = \frac{{\sum }_{i = 1}^{m} {{k}_{i} ( - 1 )}^{i} \frac{{[ {a}^{2} - {x}^{2} ( t ) ]}^{\frac{i}{2}}}{{ω}^{i}} x ( t )}{{k}_{0} x ( t )} , = {\sum }_{i = 1}^{m} \frac{{k}_{i}}{{k}_{0}} {( - 1 )}^{i} \frac{{[ {a}^{2} - {x}^{2} ( t ) ]}^{\frac{i}{2}}}{a} < {\sum }_{i = 1}^{m} \vert \frac{{k}_{i}}{{k}_{0}} \vert \frac{{[ {a}^{2} - {x}^{2} ( t ) ]}^{i}}{{ω}^{i}} \leq {\sum }_{i = 1}^{m} \vert \frac{{k}_{i}}{{k}_{0}} \vert \frac{{a}^{i}}{{ω}^{i}} \qquad ( 10 )$$

The approximate curve of ω-l is shown in FIG. 2. From FIG. 2, we can see that as the angular frequency ω increases from 0 to infinity, the value of ratio l will decreases from large to small, the general mathematical model of memristor in present invention will change from nonlinear model to linear model. In other words, as the angular frequency co increases, the general mathematical model of memristor in present invention will change from nonlinear memristor model to liner resistor model. When ratio l is less than or equal to a threshold δ, i.e. 0<l≤δ, the general mathematical model of memristor has become a liner resistor model.

As shown in FIG. 2, we call the angular frequency ωₘₐₓ corresponding to l=δ as the maximum theoretical bandwidth of memristor. Therefore, in order to realize the characteristic of a pinched hysteresis loop, the chosen parameters must satisfy the following constraint:

$${\sum }_{i = 1}^{m} \frac{\vert {k}_{i} \vert}{\vert {k}_{0} \vert} \frac{{a}^{i}}{{ω}^{i}} > l \geq δ \qquad ( 11 )$$

From the above constraint, the memory characteristics of the general mathematical model of memristor in present invention comprise: firstly, when the absolute value of polynomial coefficient k₀ decreases, the absolute value of polynomial coefficient kᵢ increases, the order m of the polynomial increases, and the amplitude a of the input sine signal increases or the angular frequency ω decreases the formula (2) will satisfy the non-linear characteristic of memristor more easily. Secondly, when the angular frequency ω is known, in order to make the general mathematical model of memristor given in formula (2) to show memory characteristics, we can increase the amplitude a of the input sine signal, increase the absolute value of polynomial coefficient kᵢ or decrease the absolute value of polynomial coefficient k₀.

5. The Generality of the General Mathematic Model of Memristor of the Present Invention to Wideband Signal

According to digital sampling theory, there is:

$$x [ n ] = a cos ( 2 π \frac{{f}_{i}}{{f}_{sap}} n ) \qquad ( 12 )$$

where fᵢ is the signal frequency, fsₐₚ is the sampling frequency. When the low frequency signal of f_{iL} and high frequency signal of f_{iH}, which have the same amplitude are respectively quantified by ADCs of sampling frequencies f_{sL}, and f_{sH}, and satisfy the following constraint:

$$OSR = \frac{{f}_{sL}}{{f}_{iL}} = \frac{{f}_{sH}}{{f}_{iH}} \qquad ( 13 )$$

Then the low sampling rate quantified sequence x_{L}[n] and the high sampling rate quantified sequence x_{H}[n] meet the following relation:

x_{L}[n]=x_{H}[n] (14)

If the corresponding coefficient matrices K_{L} and K_{H} under the two circumstances satisfy the formula: k_{iL}=rⁱ·k_{iH}, i∈[0,m] the pinched hysteresis loops of the low sampling rate quantified sequence x_{L}[n] and the high sampling rate quantified sequence x_{H}[n] are identical, which is proved as follows:

If r·f_{iL}=f_{iH}, then r⁻¹·T_{sL}=T_{sH}, where T_{sL} and T_{sL} are respectively the sampling periods corresponding to sampling frequencies f_{sL}, and f_{sH}. Then according to the formula (4), h_{L}[n]=r·h_{H}[n], where h_{L}[n] and h_{H}[n] are respectively the magnetic flux variables corresponding to the sampling frequencies f_{sL} and f_{sH}.

According to formula (4), the general mathematic model of memristor under the input of the low frequency signal of f_{iL} or the input of the high frequency signal of f_{iH} will be expanded respectively as follows:

f_{L}(h[n])=k_{0L}+k_{1L}·h_{L}[n]+ . . . +k_{iL}·(h_{L}[n])ⁱ+k_{mL}(h_{L}[n])^{m} (15)

f_{H}(h[n])=k_{0H}+k_{1H}·h_{H}[n]+ . . . +k_{iH}·(h_{H}[n])ⁱ+k_{mH}(h_{H}[n])^{m} (16)

Taking k_{iL}=rⁱ·k_{iH} and h_{L}[n]=r·h_{H}[n] into formula (15), then the following formula are obtained:

$${f}_{L} ( h [ n ] ) = {k}_{0 H} + {r}^{- 1} \cdot {k}_{1 H} \cdot r \cdot {h}_{1 H} [ n ] + {r}^{- 2} \cdot {k}_{2 H} \cdot {( r \cdot {h}_{H} [ n ] )}^{2} … + {r}^{- i} \cdot {k}_{iH} \cdot {( r \cdot {h}_{H} [ n ] )}^{i} + {r}^{- m} \cdot {k}_{mH} \cdot {( r \cdot {h}_{H} [ n ] )}^{m} = {k}_{0 H} + {k}_{1 H} \cdot {h}_{H} [ n ] + {k}_{2 H} \cdot {( {h}_{H} [ n ] )}^{2} + … + {k}_{iH} \cdot {( {h}_{H} [ n ] )}^{i} + {k}_{mH} \cdot {( {h}_{H} [ n ] )}^{m}$$

Comparing formula (16) and formula (17), then we can obtain:

f_{L}(h_{L}[n])=f_{H}(h_{H}[n])

According to formula (4), then we can obtain:

y_{L}[n]=y_{H}[n]

where y_{L}[n] and y_{H}[n] are respectively the output signals corresponding to the low sampling rate quantified sequence x_{L}[n] and the high sampling rate quantified sequence x_{H}[n]. i.e. the pinched hysteresis loops of the low sampling rate quantified sequence x_{L}[n] and the high sampling rate quantified sequence x_{H}[n] are identical.

According to the above conclusion, letting OSR=20, the pinched hysteresis loop of input signal with signal frequency f_{iH}=10 GHz and sampling signal with sampling frequency f_{sH}=200 GSPS is identical with that of input signal with signal frequency f_{iL}=5 MHz and sampling signal with sampling frequency f_{sL}=100 MSPS. It has great significance for the engineering spread and application of memristor model that mathematical model of memristor is transferred from high signal frequency and high sampling frequency to low signal frequency and low sampling frequency by configuring the polynomial coefficients of the purposed general mathematic model of memristor. The main reasons are as follows: firstly, the analog signal of GHz belongs to the high frequency signal of microwave band. Under this circumstance, the parasitic parameters in a analog signal circuit have significant impact on the analog bandwidth and the transmission of the analog signal circuit, and the design and debugging of the analog signal circuit is very difficult, thus the implementation of hardware platform can't be realized, but by a specialized company with very profound analog knowledge. To most of researchers on theory, the implementation of hardware platform in laboratory can't be realized, secondly, there is no commercial single chip ADC with the sampling frequency of several hundred GHz at current time, thirdly, the sharp rise of data bandwidth brought by high sampling frequency make the real-time calculation of back-end data processing FPGA impossible, for example, the bandwidth of 8 bit real-time data of sampling frequency 200 GSPS will reach 200 GSa/s, the real-time calculation can't realized by current commercial FPGA.

6. The Numerical Simulation of the General Mathematic Model of Memristor of the Present Invention

Matlab is used to perform the numerical simulation of the general mathematic model of memristor of the present invention to prove its correctness, and 6 the numerical simulations have been designed respectively, the parameters and results of which are shown as follows:

Numerical Simulation 1

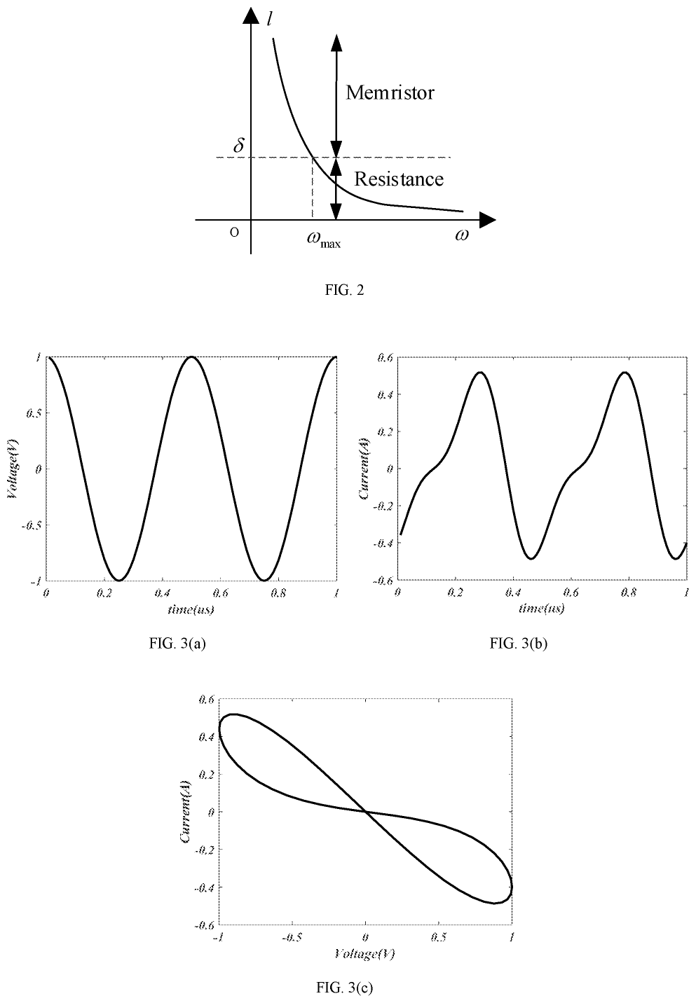

Setting coefficient matrix K₁=(−0.4,4e6,−1500,−1.25e-6,−3.125e-9), m=5 and Tₛ=10 ns, and setting a cosine input signal with amplitude a=1V and frequency fᵢ=2 MHz, the time-domain waveform curves are obtained as shown in FIG. 3, where FIG. 3(a) and FIG. 3(b) respectively show the time-domain waveform curves of input voltage signal x(t) and output current signal y(t), and FIG. 3(c) shows a characteristic curve of the general mathematic model of memristor of the present invention on a U-I plane, which is a typical pinched hysteresis loop.

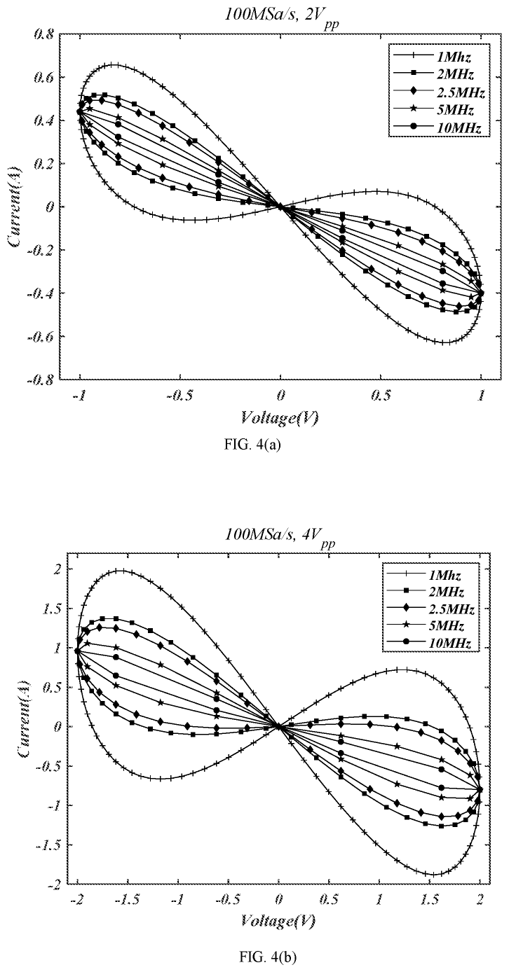

Respectively resetting the cosine input signal's amplitude (a=1V and 2V) and frequency (f i=1 MHz, 2 MHz, 2.5 MHz, 5 MHz and 10 MHz), when the sampling frequency is fixed at 100 Msa/s, the simulation results are shown in FIG. 4, where FIG. 4(a) and FIG. 4(b) show the characteristic curves of different frequencies respectively under the cosine input signal's amplitudes of 1V and 2V. Obviously, as the input signal's frequency increases, the area of pinched hysteresis loop will monotonously decrease and the slope change of pinched hysteresis loop also gradually decrease, gradually approaching a straight line. But the curves on U-I plane are pinched hysteresis loops which always pass through the coordinate origin and contract at the coordinate origin. In addition, from FIG. 4, we can also see that: firstly, when the input signal's amplitude is constant, as the input signal's frequency increases, the area of pinched hysteresis loop decreases, secondly, when the input signal's frequency is constant, as the input signal's amplitude increases, the area of pinched hysteresis loop also increases. So increasing (decreasing) the input signal's amplitude or decreasing (increasing) the input signal's frequency can increase (decrease) the area of pinched hysteresis loop.

In conclusion, the general mathematical model of memristor described in formula (2) can show the basic characteristic that can be used to identify a memristor.

Numerical Simulation 2

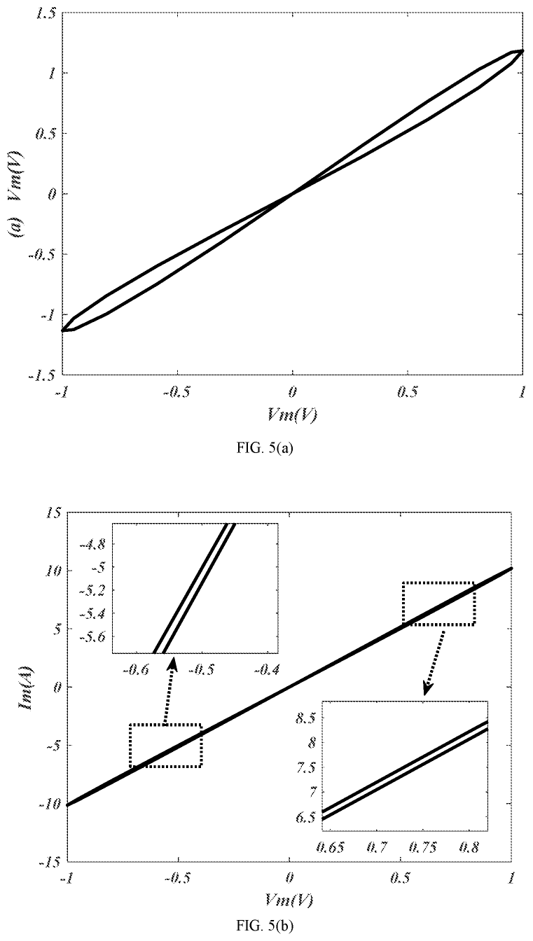

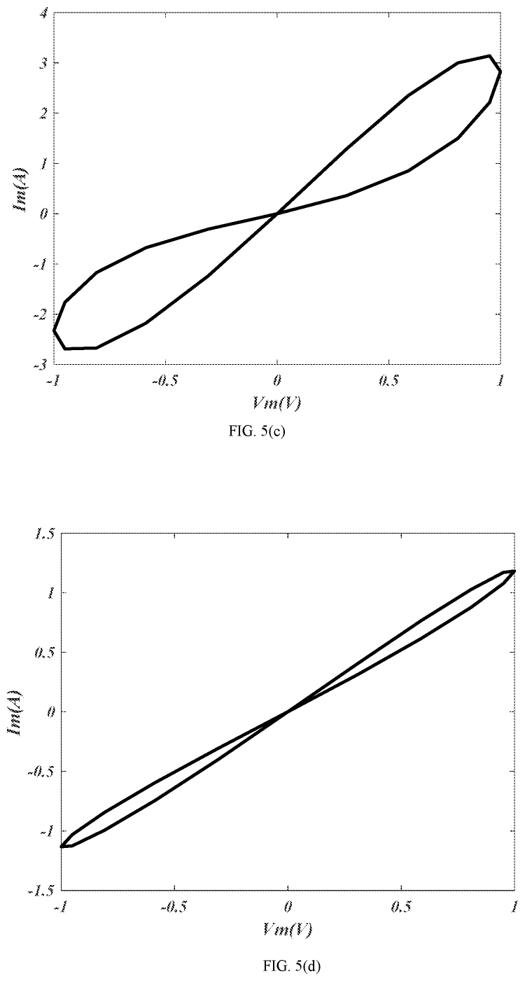

According to formula (11), polynomial coefficients kᵢ in formula (4) are related to the pinched hysteresis loop of the general mathematic model of memristor of the present invention and the frequency of the input signal. Firstly, setting a sine input signal with amplitude a=1V and frequency fᵢ=5 MHz, when coefficient matrix K₂=(1,5e6, 5e6, 5e6,7,100,500,0,−10,0,1), the pinched hysteresis loop on U-I plane is shown in FIG. 5(a). Then expanding polynomial coefficients k₁, k₂ and k₂ 10 times, the pinched hysteresis loops on U-I plane are shown in FIG. 5(b)-(d). From FIG. 5, we can also see that: as the polynomial coefficient k₀ increases, the pinched hysteresis loop will contract to a linear function, at this point, the linear term y₁(t) takes the large proportion of output y(t); as the polynomial coefficient k₁ increases, the area of pinched hysteresis loop will increase, at this point, the nonlinear term y₂(t) takes the large proportion of output y(t); as the polynomial coefficient k₂ increases, the area of pinched hysteresis loop remains almost unchanged. These are consistent with the theoretical calculation of section 2.

Numerical Simulation 3

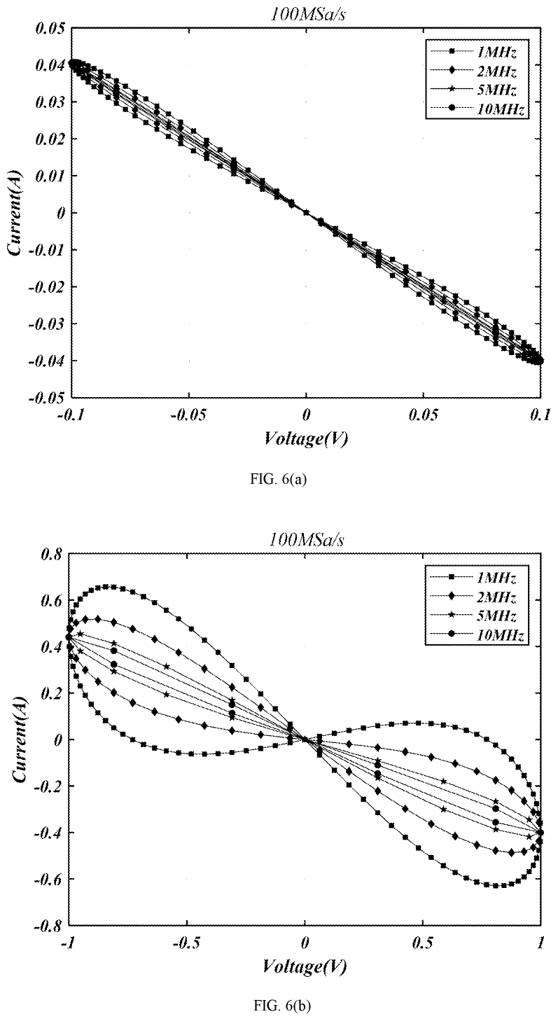

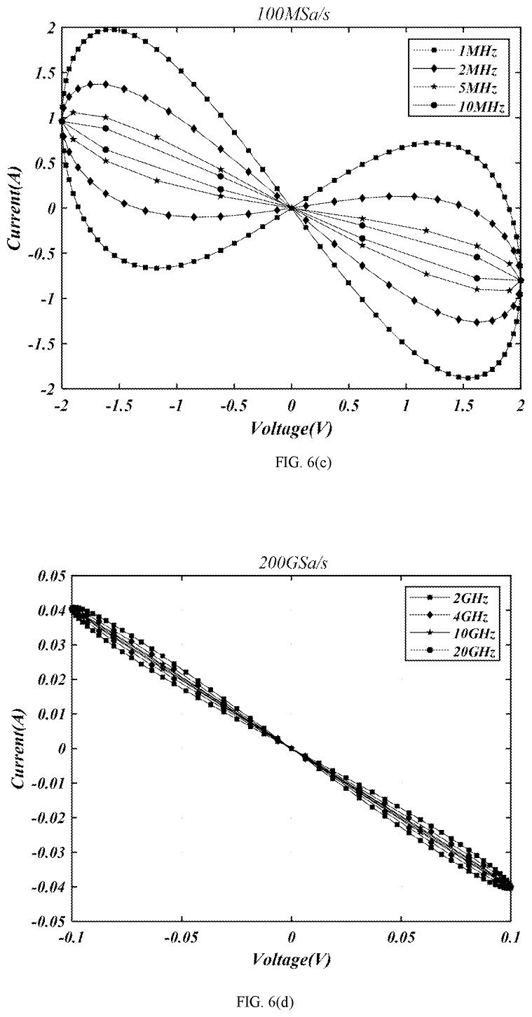

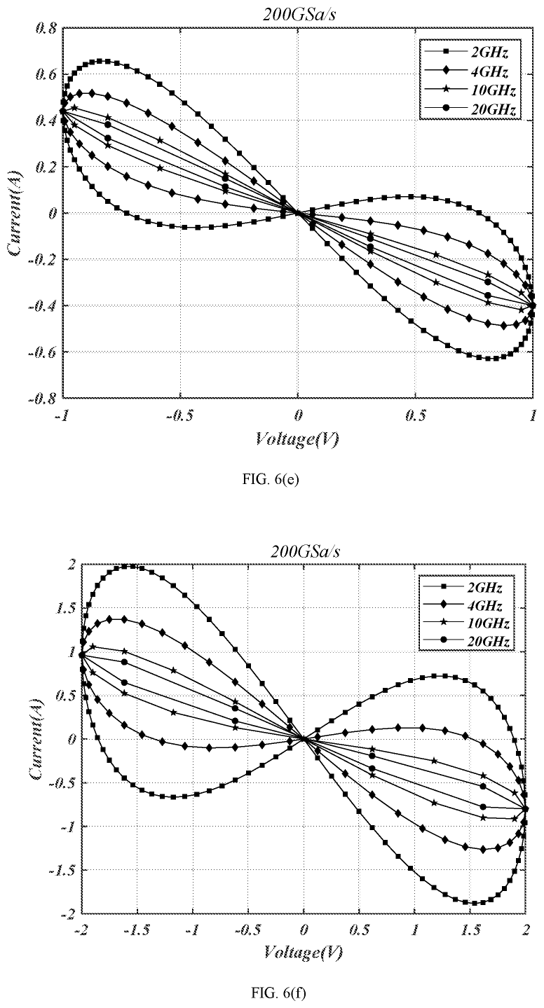

Firstly, setting coefficient matrix K_{3.0}=(−0.4, 4*10\hat{ }6, −1500, −1.26*10\hat{ }−6, −20, 0, 0,0, 0, 0, 0) and sampling frequency to 100 Msa/s, when the amplitude of input signal is 0.1V, the pinched hysteresis loops of the input signals of 1 MHz, 2 MHz, 2.5 MHz, 50 MHz and 10 MHz are shown in FIG. 6(a), when the amplitude of input signal is 1V, the pinched hysteresis loops of the input signals of 1 MHz, 2 MHz, 2.5 MHz, 50 MHz and 10 MHz are shown in FIG. 6(b), when the amplitude of input signal is 2V, the pinched hysteresis loops of the input signals of 1 MHz, 2 MHz, 2.5 MHz, 50 MHz and 10 MHz are shown in FIG. 6(c).

Setting coefficient matrix K_{3.1}=(−0.40,8.0*10\hat{ }9,−6*10\hat{ }9,−10\hat{ }4,−5*10\hat{ }4,508,−1.25*10\hat{ }5,−6*10\hat{ }7,10\hat{ }4,0,−200) and sampling frequency to 200 Gsa/s, when the amplitude of input signal is 0.1V, the pinched hysteresis loops of the input signals of 2 GHz, 4 GHz, 5 GHz, 10 GHz and 20 GHz are shown in FIG. 6(d), when the amplitude of input signal is 1V, the pinched hysteresis loops of the input signals of 2 GHz, 4 GHz, 5 GHz, 10 GHz and 20 GHz are shown in FIG. 6(e), when the amplitude of input signal is 2V, the pinched hysteresis loops of the input signals of 2 GHz, 4 GHz, 5 GHz, 10 GHz and 20 GHz are shown in FIG. 6(f). From the simulation results shown in FIG. 6, we can see that: when the amplitude of input signal is constant, the area of pinched hysteresis loop decreases with the increase of frequency; when the frequency of input signal is constant, the area of pinched hysteresis loop increases with the increase of frequency. So increasing (decreasing) the input signal's amplitude or decreasing (increasing) the input signal's frequency can increase (decrease) the area of pinched hysteresis loop.

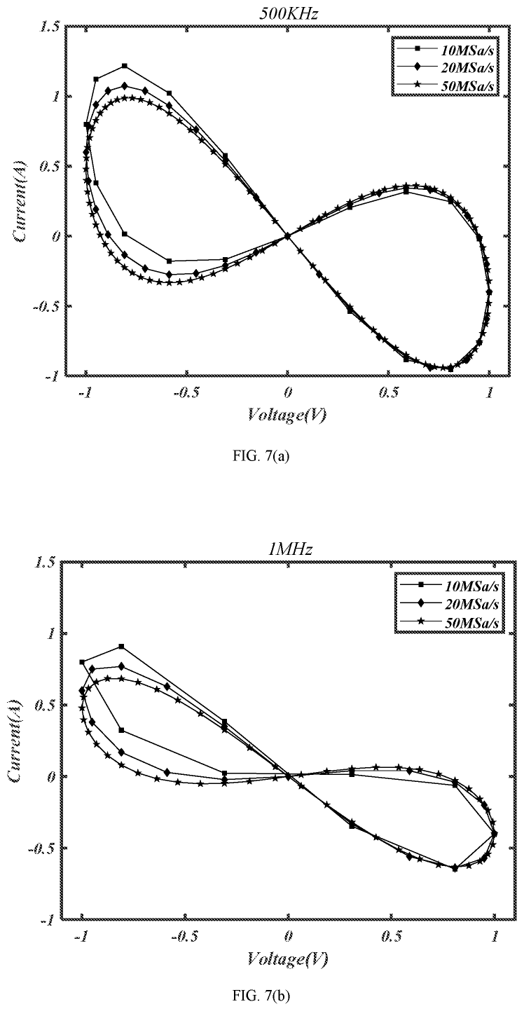

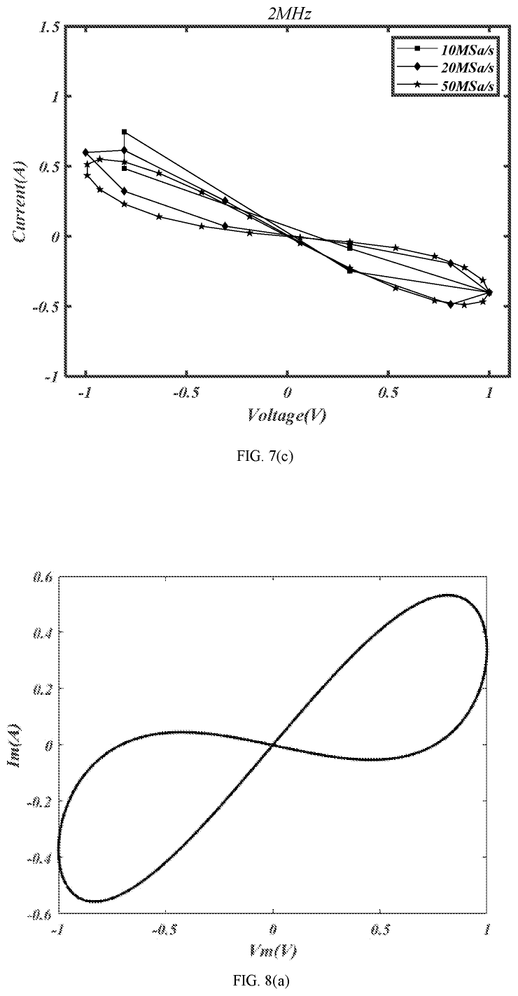

Setting coefficient matrix K_{3.0}=(−0.4, 4*10\hat{ }6, −1500, −1.26*10\hat{ }−6, −20, 0, 0,0, 0, 0, 0), when the frequency of input signal is 500 KHz, the pinched hysteresis loops under the sampling frequencies of 10 MSa/s, 20 MSa/s and 50 MSa/s are shown in FIG. 7(a); when the frequency of input signal is 1 MHz, the pinched hysteresis loops under the sampling frequencies of 10 MSa/s, 20 MSa/s and 50 MSa/s are shown in FIG. 7(b); when the frequency of input signal is 2 MHz, the pinched hysteresis loops under the sampling frequencies of 10 MSa/s, 20 MSa/s and 50 MSa/s are shown in FIG. 7(c). The pinched hysteresis loop is fitted by multiple straight line segments. The number of the straight line segments is bigger, the curve of pinched hysteresis loop is smoother. For example, when the oversampling rate is 10 (20), 10 (20) discrete data can be quantified in a signal period, thus the pinched hysteresis loop is composed of 9 (19) straight line segments. Comparing to the discrete mathematical model and the continuous mathematical model, The piecewise linear function fitting based on Nyquist sampling theorem is more simple, the pinched hysteresis loop can be obtained by just setting an appropriate oversampling rate. The above conclusion can be proved by the curves in FIG. 6 and FIG. 7.

Numerical Simulation 4

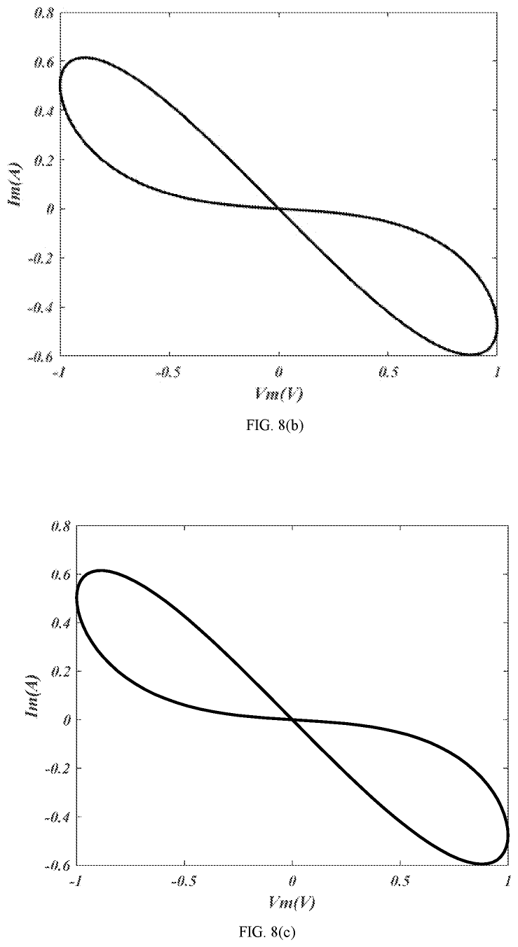

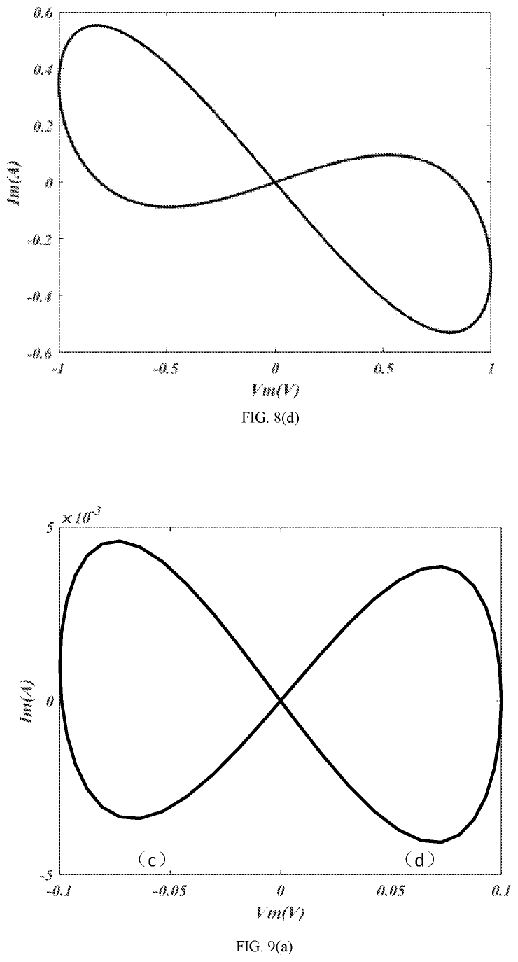

the aim of this simulation is to make the partly active characteristics of the general mathematic model of memristor be shown by setting appropriate parameters. The input signal is a sine voltage signal with amplitude of 1V and frequency of 10 Hz. The parameters of coefficient matrix K are respectively set to K_{4.0}=(0.9,−25,50), K_{4.1}=(0.9,−35,50), K_{4.2}=(−0.9,25,50) and K_{4.3}=(−0.9,35,50). The corresponding pinched hysteresis loops are respectively shown in FIG. 8(a)-FIG. 8(d). From FIG. 8(a)-FIG. 8(b) (FIG. 8(c)-FIG. 8(d)), we can see that: as the absolute value of polynomial coefficient k₁ increases, the memristor is changed from a passive (active) memristor to a partly active memristor. At the same time, the area of pinched hysteresis loop increases. Comparing FIG. 8(a) and FIG. 8(c), we can realize the switch from a passive memristor to a active memristor by changing the polarity of polynomial coefficient k₀. In conclusion, the partly active characteristics of the general mathematic model of memristor can easily and rapidly be enriched by changing the polarity and the absolute value of coefficient matrix K. The Numerical simulation proves the correctness of the theoretical analysis of section 3.

Numerical Simulation 5

The simulation parameters are as follows: m=10, Tₛ=1 us, the amplitude and the frequency of input signal are respectively 0.1V and 20 KHz. The parameters of coefficient matrix K are respectively set to:
K_{5.0}=(0,10\hat{ }5,10\hat{ }5,10\hat{ }5,7,100,500,0,−10\hat{ }10,0,0)
K_{5.1}=(0,10\hat{ }6,10\hat{ }5,10\hat{ }5,7,100,500,0,−10\hat{ }10,0,0)
K_{5.2}=(0,10\hat{ }5,10\hat{ }6,10\hat{ }5,7,100,500,0,−10\hat{ }10,0,0)
K_{5.3}=(0,10\hat{ }5,10\hat{ }5,10\hat{ }6,7,100,500,0,−10\hat{ }10,0,0)

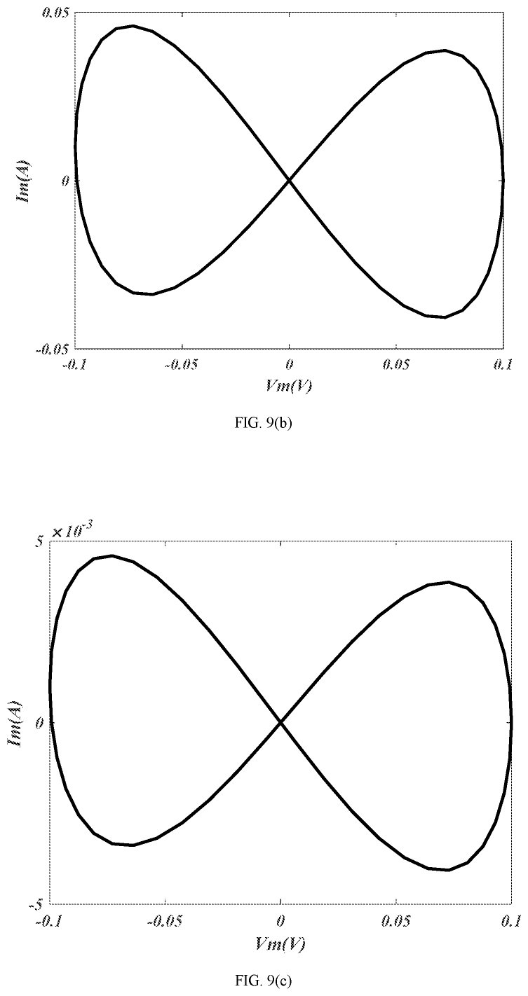

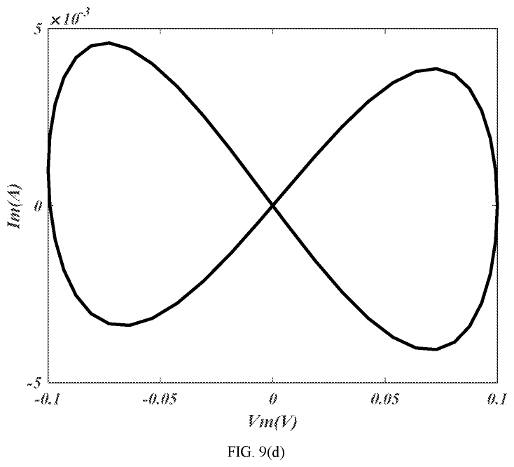

Comparing to coefficient matrix K_{5.0}, in coefficient matrices K_{5.1}, K_{5.2}, K_{5.3}, polynomial coefficient k₁ in coefficient matrix K_{5.1}, k₂ in coefficient matrix K_{5.2} and k₃ in coefficient matrix K_{5.3} are respectively increased 10 times. The pinched hysteresis loops corresponding to the four coefficient matrices are shown in FIG. 9(a)-FIG. 9(b) and we can see that: the area of pinched hysteresis loop can be increased by increasing the value of polynomial coefficient k₁, however, changing polynomial coefficient k₁ at the same order of magnitude has almost no influence on the area of pinched hysteresis loop, which proves the correctness of above theoretical analysis.

Numerical Simulation 6

Setting m=10.

Setting the parameters of high sampling as follows: f_{sH}=200 Ga/s, T_{sH}=5 ps, f_{iH}=20 GHz, a=1V, K_{H}=(−0.4,8.0*10\hat{ }9,−6*10\hat{ }9,−10\hat{ }4,−5*10\hat{ }4,508,−1.25*10\hat{ }5,−6*10\hat{ }7,10\hat{ }4,0,−200).

Setting the parameters of low sampling as follows: f^{sL}=100 Ma/s, T_{sH}=10 ns, f_{iL}=1 MHz, a=1V, K_{L}=(−0.4,8,−6*10\hat{ }−9,−10\hat{ }−23,−4*10\hat{ }−5,5.08*10\hat{ }−43,−1.25*10\hat{ }−49,−6*10\hat{ }−56,10\hat{ }−68,0,−2*10\hat{ }−88).

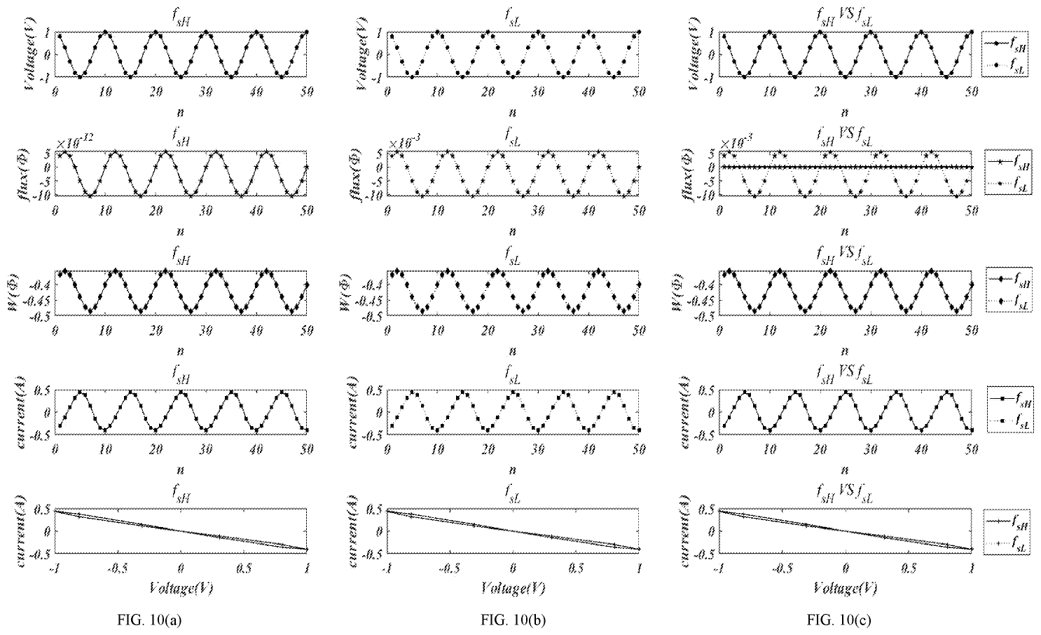

The input voltage signal (Voltage(V)), the flux (flux(Φ)), the memductance (W(Φ)), the output current signal (Current(A)) and the pinched hysteresis loop (Voltage(V)−Current(A)) of high sampling (f_{sH}) and low sampling (f_{sL}) are respectively shown in FIG. 10(a) and FIG. 10(b), the signals of high sampling (f_{sH}) and low sampling (f_{sL}) putted together are shown in FIG. 10(c). From FIG. 10, we can see that except flux, all simulation signals of high sampling (f_{sH}) and low sampling (f_{sL}) are equal. So when polynomial coefficients satisfy the formula k_{iL}=rⁱ·k_{iH} and sampling frequencies f_{sL} and f_{sH} satisfy the constraint of formula (13), the pinched hysteresis loop of high frequency input signal is identical to that of low frequency input signal.

Through the above numerical simulations, we can find that the general mathematical model of memristor purposed by present invention can show a excellent pinched hysteresis loop. It is worth noting that the pinched hysteresis loop can be shown at higher frequency of input signal and located on any places of U-I plane by changing coefficient matrix K.

FIG. 11 is a diagram of a circuit for simulating real-time reconfigurable general-purpose memristor in accordance with one embodiment of the present invention.

In the embodiment, as shown in FIG. 11, a circuit for simulating real-time reconfigurable general-purpose memristor, which is built based on a FPGA is provided comprises a system state variable generation module 1, a calculation module 2, a FIFO 3 and an output module 4.

The system state variable generation module 1 comprises a multiplier 101, an accumulator 102 and an adder 103, wherein the multiplier 101 is used to multiply an input signal x[n] and a FPGA system clock cycle Ts together to obtain a result Ts·x[n], which is outputted to the accumulator 102 for accumulation to obtain an accumulated value, which is denoted by:

$$Ts \cdot {\sum }_{j = 1}^{n} x [ j ]$$

The accumulated value is outputted to the adder 103 to add a system state variable's initial value h[0], then a system state variable h[n] is obtained:

$$h [ n ] = Ts {\sum }_{j = 1}^{n} x [ j ] + h [ 0 ]$$

where the input signal x[n] is a voltage signal or current signal, the system state variable h[n] is a charge or magnetic flux variable.

In the embodiment, a 48 bit adder is used to build the accumulator 102 to realize the accumulation of input signal x[n].

The calculation module 2, which comprises m reconfigurable calculating units operating in m grades cascaded pipeline mode is used to implement m polynomial multiply-accumulate operations. As shown in FIG. 11, each reconfigurable calculating unit comprises 2 multipliers 2011 2021, 1 adder 202 and 1 D flip-flop 203.

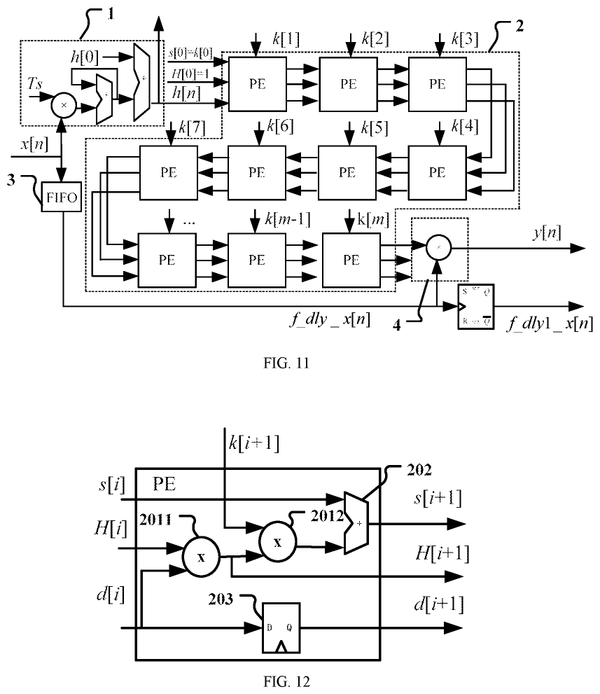

As shown in FIG. 12, to i+1^{th} reconfigurable calculating unit, i=0,1,2, . . . , m−1, its inputs are polynomial coefficient k[i+1], the adder 202's input s[i] and the first multiplier 2011's inputs H[i] and d[i], its outputs are the adder 202's output s[i+1], the second multiplier's output H[i+1] and the delay signal d[i+1], the mathematical relation of the inputs and the outputs is:

$$\{ \begin{matrix}H [ i + 1 ] = H [ i ] \cdot d [ i ] \\ s [ i + 1 ] = s [ i ] + k [ i + 1 ] \cdot H [ i + 1 ] \\ d [ i + 1 ] = d [ i ]\end{matrix}$$

where the first multiplier 2011 is used to multiply inputs H[i] and d[i] together to obtain the output H[i+1], the second multiplier 2012 is used to multiply the first multiplier 2011's output H[i+1] and polynomial coefficient k[i+1] together to obtain an output k[i+1]·H[i+1], the adder 202 is used to add the input s[i] and the output k[i+1]·H[i+1] together to obtain the output s[i+1], the D flip-flop 203 is used to delay the input did one clock period to obtain the delay signal d[i+1].

To the 1^{st} reconfigurable calculating unit, its input d[0] is the system state variable h[n] outputted by system state variable generation module, its input H[0] is 1, its input s[0] is the polynomial coefficient k(0).

Wherein the number m of the polynomials is determined as follows:

Determining the maximum amplitude aₘₐₓ and the minimum frequency ωₘₐₓ in respectively according to the amplitude and the frequency of the zero-DC component AC signal in the input signal x[n], then determining the range of the system state variable h[n] as follows:

$$[ - \frac{{a}_{max}}{{ω}_{min}} , \frac{{a}_{max}}{{ω}_{min}} ]$$

In the range of the system state variable h[n], using McLaughlin formula to perform a m-order polynomial fitting of memristance or memductance f(h[n]) about the system state variable h[n] to obtain a fitting function g(h[n]), where the maximum fitting error ε_{M} is:

$${E}_{M} = \vert \frac{f ( \frac{{a}_{max}}{{ω}_{min}} ) - g ( \frac{{a}_{max}}{{ω}_{min}} )}{f ( \frac{{a}_{max}}{{ω}_{min}} )} \vert$$

The value of the polynomial order m should satisfy ε_{M}≤ε₀, where ε₀ is the acceptable maximum fitting error.

Wherein the polynomial coefficient k[i] of the i^{th} order, i=0, 1, 2, . . . , m is obtained by expanding the mathematical model of memristor to be simulated, i.e. the memristance or memductance f(h[n]) at time n into a polynomial according to McLaughlin formula:

$$f ( h [ n ] ) = {\sum }_{i = 0}^{m} k [ i ] \cdot {( h [ n ] )}^{i}$$

The output s[m] of the m^{th} reconfigurable calculating unit is taken as the memristance or memductance f(h[n]).

FIFO 3 is used to delay the input signal x[n] m+39 clock periods to obtain a delayed input signal f_dly_x[n].

Output module 4 comprises a multiplier, where the multiplier is used to multiply the delayed input signal f_dly_x[n] and the memristance or memductance f(h[n]) outputted by the m^{th} reconfigurable calculating unit to obtain an output signal y[n], the output signal y[n] is a current signal or a voltage signal. In the embodiment, as shown in FIG. 11, the delayed input signal f_dly_x[n] is further delayed by a RS flip-flop to obtain a delayed input signal f_dly1_x[n], which synchronize with output signal y[n].

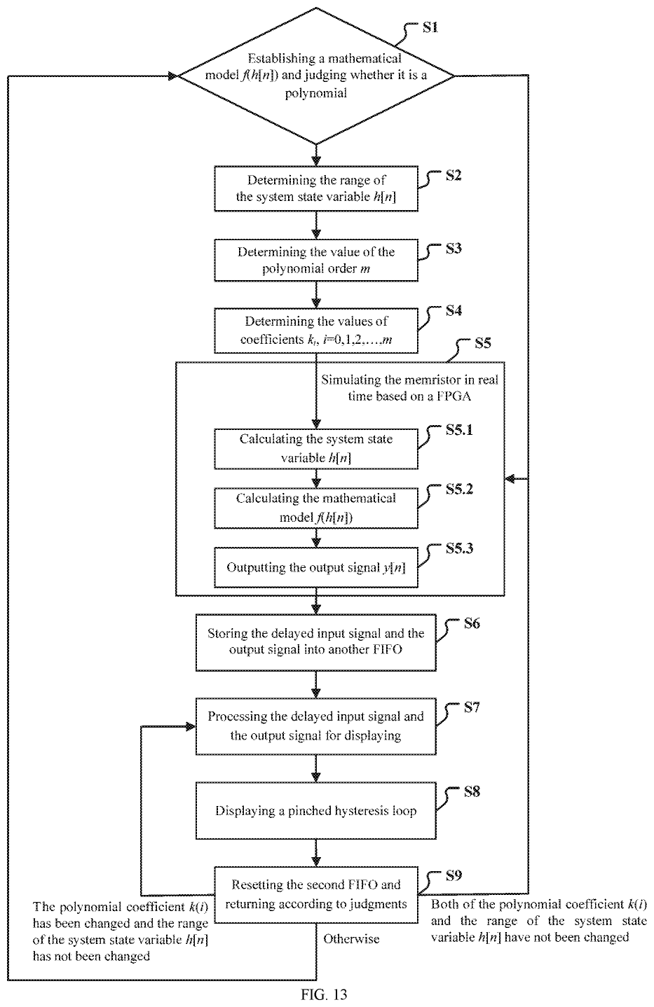

FIG. 13 is a flow diagram of a method for simulating real-time reconfigurable general-purpose memristor in accordance with one embodiment of the present invention.

In one embodiment of present invention, As shown in FIG. 13, a method for simulating real-time reconfigurable general-purpose memristor in accordance with one embodiment of the present invention comprises:

Step S1: Establishing a Mathematical Model f(h[n]) and Judging Whether it is a Polynomial

Establishing a mathematical model f(h[n]) for a memristor, and judging whether it is a polynomial about a system state variable h[n], if not, going to step S2, if it is, then determining an m-order of the mathematical model/(h [n]) about the system state variable h[n] and going to step S5.

Step S2: Determining the Range of the System State Variable h[n]

Determining the maximum amplitude aₘₐₓ and the minimum frequency ωₘᵢₙ respectively according to the amplitude and the frequency of the zero-DC component AC signal in the input signal x[n], then determining the range of the system state variable h[n] as follows:

$$[ - \frac{{a}_{max}}{{ω}_{min}} , \frac{{a}_{max}}{{ω}_{min}} ]$$

Step S3: Determining the Value of the Polynomial Order m

In the range of the system state variable h[n], using McLaughlin formula to perform a m-order polynomial fitting of memristance or memductance f(h[n]) about the system state variable h[n] to obtain a fitting function g(h[n]), where the maximum fitting error ε_{M} is:

$${E}_{M} = \vert \frac{f ( \frac{{a}_{max}}{{ω}_{min}} ) - g ( \frac{{a}_{max}}{{ω}_{min}} )}{f ( \frac{{a}_{max}}{{ω}_{min}} )} \vert$$

The value of the polynomial order m should satisfy ε_{M}≤ε₀, where ε₀ is the acceptable maximum fitting error.

Step S4: Determining the Values of Coefficients kᵢ, i=0, 1, 2, . . . , m

m+1 polynomial coefficients kᵢ, i=0, 1, 2, . . . , m of the mathematical model f(h[n]) are determined according to McLaughlin formula.

Step S5: Simulating the Memristor in Real Time Based on a FPGA

In the FPGA, the following calculations are performed:

Step S5.1: Calculating the System State Variable h[n]

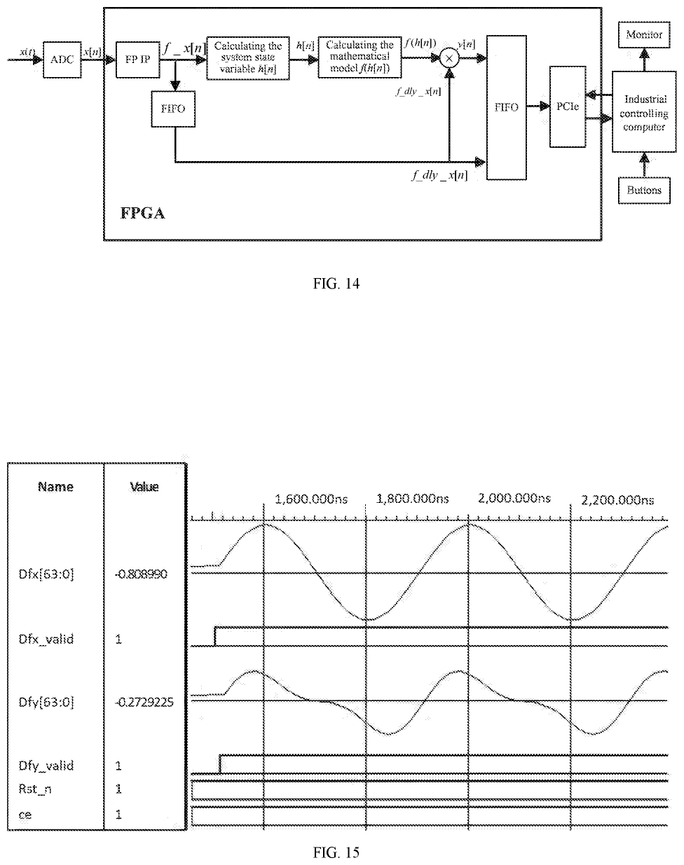

As shown in FIG. 14, to an input signal x[n], converting it into a single precision floating-point data f_x[n] by using the fixed point number to floating point number IP core in the FPGA, where the range of the single precision floating-point data f_x[n] is [−1, 1], then, calculating an system state variable h[n], i.e. the charge or magnetic flux at time n:

$$h [ n ] = Ts {\sum }_{j = 1}^{n} f\_x [ j ] + h [ 0 ]$$

where Ts is the system clock cycle of the FPGA, f_x[j] is the j^{th} sampling point of the single precision floating-point data f_x[n], h[0] is the initial value of the system state variable h[n];

Step S5.2: Calculating the Mathematical Model f(h[n]), i.e. the Memristance or Memductance f(h[n]) of the Memristor:

$$f ( h [ n ] ) = {\sum }_{i = 0}^{m} {k}_{i} \cdot {( h [ n ] )}^{i}$$

Step S5.3: Outputting the Output Signal y[n]

As shown in FIG. 14, sending the single precision floating-point data f_x[n] to a FIFO, i.e. the first FIFO for delay to obtain a delayed data f_dly_x[n], which makes the data of the read port of the first FIFO, i.e. delayed data f_dly_x[n] aligned with the memristance or memductance f(h[n]) along the time, then calculating the output signal y[n]:

y[n]=f(h[n])·f_dly_x[n]

where the input signal x[n] is a voltage signal or current signal, the output signal y[n] is a current signal or voltage signal;

Step S6: Storing the Delayed Input Signal and the Output Signal into Another FIFO

Storing the delayed data f_dly_x[n] and the output signal y[n] into another FIFO, i.e. the second FIFO, when the second FIFO is written full, reading out the delayed data f_dly_x[n] and the output signal y[n] from the second FIFO and send them to a signal processing and displaying module.

Step S7: Processing the Delayed Input Signal and the Output Signal for Displaying

In the signal processing and displaying module, multiplying the vertical sensitivity of input signal displaying and the half of the number of the vertical divisions in waveform display area to obtain a display range R₁, multiplying the vertical sensitivity of memristor output displaying and the half of the number of the vertical divisions in waveform display area to obtain a display range R₂.

Then processing the delayed data f_dly_x[n] as follows:

$$\begin{matrix}{d}_{x} ( n ) = f\_dly \_x [ n ] \cdot {R}_{1} \\ {d}_{x\_HL} ( n ) = \frac{{d}_{x} ( n )}{max ( \vert {d}_{x} ( n ) \vert )} \cdot {R}_{1}\end{matrix}$$

where max(|dₓ(n)|) represents choosing the data which absolute value is maximum from the sequence of data dₓ(n), data d_{x_HL}(n)∈[−1, 1].

Processing the output data y[n] as follows:

$$\begin{matrix}{d}_{y} ( n ) = y [ n ] \cdot \frac{{R}_{2}}{{R}_{1}} \\ {d}_{y\_HL} ( n ) = \frac{{d}_{y} ( n )}{max ( \vert {d}_{y} ( n ) \vert )} \cdot {R}_{2}\end{matrix}$$

where max(|d_{y}(n)|) represents choosing the data which absolute value is maximum from the sequence of data d_{y}(n), data d_{y_HL}(n)∈[−1, 1].

Step S8: Displaying a Pinched Hysteresis Loop

Taking the center of the waveform display area of the X-Y view of a digital oscilloscope as a coordinate origin (0, 0), respectively taking the data d_{x_HL}(n) as a x-coordinate and the data d_{y_HL}(n) as a y-coordinate, then sending the pixel (d_{x_HL}(n), d_{y_HL}(n)) as the pixel to be highlighted into the digital oscilloscope's LCD to perform a display of Lissajous figure, i.e. display a pinched hysteresis loop; meanwhile, sending the data dₓ(n) and the data d_{y}(n) into the digital oscilloscope for caching and then performing a waveform display of time-domain.

In the embodiment, step S7 and step S8 are realized in an industrial controlling computer, and a monitor is taken as the LCD of the digital oscilloscope.

Step S9: Resetting the Second FIFO and Returning According to Judgments

Resetting the second FIFO, then judging according to the following rules: if both of the polynomial coefficient k(i) and the range of the system state variable h[n] have not been changed, then going to step S6, if the polynomial coefficient k(i) has been changed and the range of the system state variable h[n] has not been changed, then going to step S5, otherwise, going to step S1.

Functional Hardware Simulation

In order to evaluate the performance of the FPGA based circuit for simulating real-time reconfigurable general-purpose memristor, i.e. the performance of the present invention, we performed a functional simulation, and compared it with the relevant prior arts.

In the embodiment, hardware programming language Verilog, software development environment Vivado 2020.1 and functional simulation software Xsim are used to the hardware functional simulation of the present invention.

Firstly, a 14 bits signed digital discrete sine signal of 4096 points is generated by Matlab software, and a waveform generating module is built base on DDS (Direct Digital Frequency Synthesis) in a FPGA. The 14 bits signed digital discrete sine signal is stored in a waveform ROM of the FPGA. Reading the 14 bits signed digital discrete sine signal stored in the waveform ROM, a sine signal with adjustable frequency is outputted through adjusting the frequency control word (step value of waveform ROM's read address). DDS technology belongs to the prior art, the details of DDS are not described here.

The coefficient matrix K is (0.4,−3.0*10\hat{ }6,4.5*10\hat{ }8,−10\hat{ }2,1.5*10\hat{ }6,50.8,−125,6,100,10,−200), clock cycle Ts=10 ns. For the convenience of comparative analysis of results of hardware and software simulations, the output data of the circuit for simulating real-time reconfigurable general-purpose memristor is double precision float-point data. The timing diagram of hardware simulation is shown in FIG. 15, in which clk, rst_n and ce are respectively the system clock of 100 MHz, low-level valid reset signal and module enable signal. Data dfx and dfy are respectively the input voltage signal and output current signal of the circuit for simulating real-time reconfigurable general-purpose memristor. dfx_valid (dfy_valid) is high level means outputting data dfx (dfy). In FIG. 15, dfx_valid and dfy_valid are always at high level, which prove that the circuit for simulating real-time reconfigurable general-purpose in accordance with present invention can realize real-time calculation in a FPGA and real-time calculation speed can reach 12.8 Gbps.

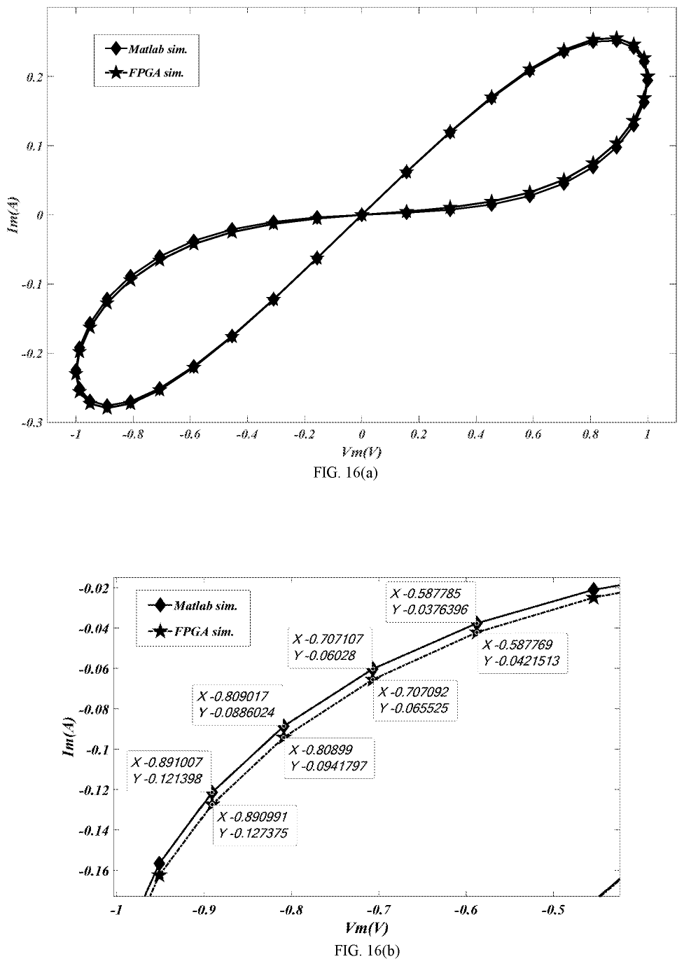

The double precision float-point data outputted by the circuit for simulating real-time reconfigurable general-purpose are imported into Matlab software and compared with the pinched hysteresis loop obtained by using Matlab software to simulate the general mathematic model of memristor, which are shown in FIG. 16(a). From the FIG. 16(a), we can see that each pinched hysteresis loop is composed of 40 points, i.e. the oversampling rate is 40, and the pinched hysteresis loops of hardware simulation and software simulation are virtually identical. The partial enlarged view of the pinched hysteresis loops of the simulations is shown in FIG. 16(b). The data calculation of one period can be completed only in 400 ns by the FPGA.

Then, we build a circuit for simulating real-time reconfigurable general-purpose with 10-order nonlinear polynomial in the FPGA to perform rapid configurable experiments for 6 memristor models of the prior art. The input parameters of the 6 memristor models, the frequencies and amplitudes (fixed at 1V) of the corresponding bipolar input sine signals, sampling frequency, the amplitudes of output signals, calculation times of Matlab software simulation and calculation times of hardware simulation are respectively shown in Table 4.

TABLE 1

| | | | | | | Sampling | | Calculation time | |
|---|---|---|---|---|---|---|---|---|---|
| | Memristor | Model coefficients | | | frequency | frequency | amplitude | (s) | |
| No | model | a | b | c | (Hz) | (Hz) | (A) | Matlab | FPGA |
| 1 | a + btanhx | 10⁻⁴ | 10 | / | 2 * 10³ | 10⁵ | 1.1 * 10⁻³ | 7.3 | 0.02 |
| 2 | acosx | 0.5 | / | / | 0.5 | 50 | 0.49 | 17.9 | 2 |
| 3 | asin(cx) + bx² | 3.5 | 3 * 10⁷ | 5 | 1 * 10⁶ | 10⁸ | 5 * 10⁻⁶ | 15.7 | 10⁻⁶ |
| 4 | a ± bx | 10³ | 3.2 * 10⁸ | / | 2 * 10⁴ | 10⁶ | 4180 | 10.3 | 5 * 10⁻⁵ |
| 5 | a + bx² | −0.8 | 3 * 10⁸ | / | 5 * 10³ | 2.5 * 10⁵ | 0.633 | 10 | 2 * 10⁻⁴ |
| 6 | a + bx² + cx⁴ | −0.02 | 10⁹ | −10⁻² | 5 * 10⁴ | 2.5 * 10⁶ | 1.5 * 10⁻² | 9.4 | 2 * 10⁻⁵ |

From table 4, we can see that the amplitudes of the output signals of the circuit for simulating real-time reconfigurable general-purpose are related to input parameters.

In table 4, the one cycle's calculation times of the input signals with different signal frequencies for different memristor model are given (The fixed delay time 390 ns has been neglected for FPGA, i.e. hardware simulation). From table 4, we can see that the circuit for simulating real-time reconfigurable general-purpose in accordance with present invention can simulate various memristor model in prior art, and comparing with Matlab software, its calculation time are greatly reduced.

While illustrative embodiments of the invention have been described above, it is, of course, understand that various modifications will be apparent to those of ordinary skill in the art. Such modifications are within the spirit and scope of the invention, which is limited and defined only by the appended claims

What is claimed is:

1. A circuit for simulating real-time reconfigurable general-purpose memristor, which is built based on a FPGA, comprising:
a system state variable generation module, which comprises a multiplier, an accumulator and an adder, wherein the multiplier is used to multiply an input signal x[n] and a FPGA system clock cycle Ts together to obtain a result Ts·x[n], and result Ts·x[n] is outputted to the accumulator for accumulation to obtain an accumulated value, which is denoted by:
$$Ts \cdot {{\sum }^{n}}_{j = 1} x [ j ]$$
the accumulated value is outputted to the adder to add a system state variable's initial value h[0], then a system state variable h[n] is obtained:
$$h [ n ] = T s {\sum }_{j = 1}^{n} x [ j ] + h [ 0 ]$$
where the input signal x[n] is a voltage signal or current signal, the system state variable h[n] is a charge or magnetic flux variable;
a calculation module, which comprises m reconfigurable calculating units operating in m grades cascaded pipeline mode, and is used to implement m polynomial multiply-accumulate operations, wherein each reconfigurable calculating unit comprises two multipliers, one adder and one D flip-flop;
to i+1^{th} reconfigurable calculating unit, i=0,1,2, . . . , m−1, its inputs are polynomial coefficient k[i+1], the adder's input s[i] and the first multiplier's inputs H[i] and d[i], its outputs are the adder's output s[i+1], the second multiplier's output H[i+1] and the delayed signal d[i+1], the mathematical relation of the inputs and the outputs is:
$$\{ \begin{matrix}H [ i + 1 ] = H [ i ] \cdot d [ i ] \\ s [ i + 1 ] = s [ i ] + k [ i + 1 ] \cdot H [ i + 1 ] \\ d [ i + 1 ] = d [ i ]\end{matrix}$$
where the first multiplier is used to multiply inputs H[i] and d[i] together to obtain the output H[i+1], the second multiplier is used to multiply the first multiplier's output H[i+1] and polynomial coefficient k[i+1] together to obtain an output k[i+1]·H[i+1], the adder is used to add the input s[i] and the output k[i+1]·H[i+1] together to obtain the output s[i+1], the D flip-flop is used to delay the input d[i] to obtain the delay signal d[i+1];
to the 1^{st} reconfigurable calculating unit, its input d[0] is the system state variable h[n] outputted by system state variable generation module, its input H[0] is 1, its input s[0] is the polynomial coefficient k(0);
wherein the number m of the polynomials is determined as follows:
determining the maximum amplitude aₘₐₓ and the minimum frequency ωₘᵢₙ respectively according to the amplitude and the frequency of the zero-DC component AC signal in the input signal x[n], then determining the range of the system state variable h[n] as follows:
$$[ - \frac{{a}_{max}}{{ω}_{min}} , \frac{{a}_{max}}{{ω}_{min}} ]$$
in the range of the system state variable h[n], using McLaughlin formula to perform a m-order polynomial fitting of memristance or memductance f(h[n]) about the system state variable h[n] to obtain a fitting function g(h[n]), where the maximum fitting error ε_{M} is:
$${ε}_{M} = \vert \frac{f ( \frac{{a}_{max}}{{ω}_{min}} ) - g ( \frac{{a}_{max}}{{ω}_{min}} )}{f ( \frac{{a}_{max}}{{ω}_{min}} )} \vert$$
the value of the polynomial order m should satisfy ε_{M}≤ε₀, where ε₀ is the acceptable maximum fitting error;
wherein the polynomial coefficient k[i] of the i^{th} order, i=0, 1, 2, . . . , m is obtained by expanding the mathematical model of memristor to be simulated, i.e. the memristance or memductance f(h[n]) at time n into a polynomial according to McLaughlin formula:
$$f ( h [ n ] ) = {\sum }_{i = 0}^{m} k [ i ] \cdot {( h ( n ) )}^{i}$$
the output s[m] of the m^{th} reconfigurable calculating unit is taken as the memristance or memductance f(h[n]);
a FIFO, which is used to delay the input signal x[n] m+39 clock periods to obtain a delayed input signal;
a output module, which comprises a multiplier, where the multiplier is used to multiply the delayed input signal and the memristance or memductance f(h[n]) outputted by the m^{th} reconfigurable calculating unit to obtain an output signal y[n], the output signal y[n] is a current signal or a voltage signal.

2. A method for simulating real-time reconfigurable general-purpose memristor, comprising:
(1). establishing a mathematical model f(h[n]), for a memristor, and judging whether it is a polynomial about a system state variable h[n], if not, going to step (2), if it is, then determining an order m of the mathematical model f(h[n]) about the system state variable h[n] and going to step (5);
(2). determining the maximum amplitude aₘₐₓ and the minimum frequency ωₘᵢₙ respectively according to the amplitude and the frequency of the zero-DC component AC signal in an input signal x[n], then determining the range of the system state variable h[n] as follows:
$$[ - \frac{{a}_{max}}{{ω}_{min}} , \frac{{a}_{max}}{{ω}_{min}} ]$$
(3). in the range of the system state variable h[n], using McLaughlin formula to perform a m-order polynomial fitting of memristance or memductance f(h[n]) about the system state variable h[n] to obtain a fitting function g(h[n]), where the maximum fitting error ε_{M} is:
$${ε}_{M} = \vert \frac{f ( \frac{{a}_{max}}{{ω}_{min}} ) - g ( \frac{{a}_{max}}{{ω}_{min}} )}{f ( \frac{{a}_{max}}{{ω}_{min}} )} \vert$$
the value of the polynomial order m should satisfy ε_{M}≤ε₀, where ε₀ is the acceptable maximum fitting error;
(4). determining m+1 polynomial coefficients kᵢ, i=0, 1, 2, . . . , m of the mathematical model f(h[n]) according to McLaughlin formula;
(5). simulating the memristor in real time based on a FPGA, i.e. performing the following calculations in the FPGA:
5.1) firstly, to input signal x[n], converting it into a single precision floating-point data f_x[n] by using the fixed point number to floating point number IP core in the FPGA, where the range of the single precision floating-point data f_x[n] is [−1, 1], then, calculating an system state variable h[n], i.e. the charge or magnetic flux at time n:
$$h [ n ] = T s {\sum }_{{j = 1}^{}}^{n} f\_x [ j ] + h [ 0 ]$$
where Ts is the system clock cycle of the FPGA, f_x[j] is the j^{th} sampling point of the single precision floating-point data f_x[n], h[0] is the initial value of the system state variable h[n];
5.2) calculating the mathematical model f(h[n]), i.e. the memristance or memductance f(h[n]) of the memristor:
$$f ( h [ n ] ) = {\sum }_{i = 0}^{m} {k}_{i} \cdot {( h [ n ] )}^{i}$$
5.3) meanwhile, sending the single precision floating-point data f_x[n] to a FIFO, i.e. the first FIFO for delay to obtain a delayed data f_dly_x[n], which makes the data of the read port of the first FIFO, i.e. delayed data f_dly_x[n] aligned with the memristance or memductance f(h[n]) along the time, then calculating the output signal y[n]:
y[n]=f(h[n])·f_dly_x[n]
where the input signal x[n] is a voltage signal or current signal, the output signal y[n] is a current signal or voltage signal;
(6). storing the delayed data f_dly_x[n] and the output signal y[n] into another FIFO, i.e. the second FIFO, when the second FIFO is written full, reading out the delayed data f_dly_x[n] and the output signal y[n] from the second FIFO and send them to a signal processing and displaying module;
(7). in the signal processing and displaying module, multiplying the vertical sensitivity of input signal displaying and the half of the number of the vertical divisions in waveform display area to obtain a display range R₁, multiplying the vertical sensitivity of memristor output displaying and the half of the number of the vertical divisions in waveform display area to obtain a display range R₂;
then processing the delayed data f_dly_x[n] as follows:
$$\begin{matrix}{d}_{x} ( n ) = f\_dly \_x [ n ] \cdot {R}_{1} \\ {d}_{x\_HL} ( n ) = \frac{{d}_{x} ( n )}{max ( \vert {d}_{x} ( n ) \vert )} \cdot {R}_{1}\end{matrix}$$
where max(|dₓ(n)|) represents choosing the data which absolute value is maximum from the sequence of data dₓ(n), data d_{x_HL}(n)∈[−1, 1];
processing the output data y[n] as follows:
$$\begin{matrix}{d}_{y} ( n ) = y [ n ] \cdot \frac{{R}_{2}}{{R}_{1}} \\ {d}_{y\_HL} ( n ) = \frac{{d}_{y} ( n )}{max ( \vert {d}_{y} ( n ) \vert )} \cdot {R}_{2}\end{matrix}$$
where max(|d_{y}(n)|) represents choosing the data which absolute value is maximum from the sequence of data d_{y}(n), data d_{y_HL}(n)∈[−1, 1];
(8). taking the center of the waveform display area of the X-Y view of a digital oscilloscope as a coordinate origin (0, 0), respectively taking the data d_{x_HL}(n) as a x-coordinate and the data d_{y_HL}(n) as a y-coordinate, then sending the pixel (d_{x_HL}(n), d_{y_HL}(n)) as the pixel to be highlighted into the digital oscilloscope's LCD to perform a display of Lissajous figure, i.e. display a pinched hysteresis loop; meanwhile, sending the data dₓ(n) and the data d_{y}(n) into the digital oscilloscope for caching and then performing a waveform display of time-domain;
(9). resetting the second FIFO, then judging according to the following rules: if both of the polynomial coefficient k(i) and the range of the system state variable h[n] have not been changed, then going to step (6), if the polynomial coefficient k(i) has been changed and the range of the system state variable h[n] has not been changed, then going to step (5), otherwise, going to step (1).
